(19) United States
(12) Patent Application Publication
(10) Pub. No.: US 2023/0307350 A1
(43) Pub. Date: Sep. 28, 2023

(54) MICROELECTRONIC DEVICES INCLUDING STAIRCASE STRUCTURES, AND RELATED METHODS, MEMORY DEVICES, AND ELECTRONIC SYSTEMS

(71) Applicant: Micron Technology, Inc., Boise, ID (US)

(72) Inventors: Lifang Xu, Boise, ID (US); Indra V. Chary, Boise, ID (US); Richard J. Hill, Boise, ID (US)

(21) Appl. No.: 17/701,509

(22) Filed: Mar. 22, 2022

(51) Int. Cl. H01L 23/522; H01L 23/528; H01L 23/535; H01L 21/768

(52) U.S. Cl. CPC H01L 23/5221; H01L 23/5283; H01L 23/535; H01L 21/76816; H01L 21/76895

(57) ABSTRACT

A microelectronic device includes a stack structure having blocks separated by dielectric slot structures and each including a vertically alternating sequence of conductive structures and insulative structures arranged in tiers. At least one of the blocks includes an upper stadium structure, two crest regions, a lower stadium structure, and two bridge regions. The upper stadium structure extends from and between two of the dielectric slot structures, and includes staircase structures having steps including edges of some of the tiers. The two crest regions are horizontally offset from the upper stadium structure. The lower stadium structure is below the upper stadium structure, is interposed between the two crest regions, and includes additional staircase structures. The two bridge regions are interposed between the lower stadium structure and the two of the dielectric slot structures, and extend between the two crest regions. Related memory devices, electronic systems, and methods are also described.

### TECHNICAL FIELD

The disclosure, in various embodiments, relates generally to the field of microelectronic device design and fabrication. More specifically, the disclosure relates to methods of forming microelectronic devices including staircase structures, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices, such as Flash memory devices. A conventional Flash memory device generally includes a memory array having charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a “three-dimensional NAND” memory device (which may also be referred to herein as a “3D NAND” memory device), a type of vertical memory device, not only are the memory cells arranged in row and column fashion in a horizontal array, but tiers of the horizontal arrays are stacked over one another (e.g., as vertical strings of memory cells) to provide a “three-dimensional array” of the memory cells. The stack of tiers vertically alternate conductive materials with insulative (e.g., dielectric) materials. The conductive materials function as control gates for access lines (e.g., word lines) of the memory cells. Vertical structures (e.g., pillars comprising channel structures and tunneling structures) extend along the vertical string of memory cells. A drain end of a string is adjacent one of the top and bottom of the vertical structure, while a source end of the string is adjacent the other of the top and the bottom of the pillar. The drain end is operably connected to a bit line, while the source end is operably connected to a source structure (e.g., a source plate, a source line). A 3D NAND memory device also includes electrical connections between, the access lines and other conductive structures of the device so that the memory cells of the vertical strings can be selected for writing, reading, and erasing operations.

Some 3D NAND memory devices include so-called “staircase” structures having “steps” (also referred to as “stairs”) at edges (e.g., ends) of the tiers of the stack. The steps have treads (e.g., upper surfaces) defining contact regions of conductive structures of the device, such as of access lines (e.g., local access lines), which may be formed by the conductive materials of the tiered stack. Contact structures may be provided in physical contact with the steps to facilitate electrical access to the conductive structures associated with the steps. The contact structures may be in electrical communication, by way of conductive routing structures, to additional contact structures that communicate to a source/drain region. String drivers drive access line voltages to write to or read from the memory cells controlled via the access lines.

A continued goal in the microelectronic device fabrication industry is to reduce the footprint of the features of microelectronic devices so as to maximize the number of devices, and functional features thereof, in a given structural area. However, as device and feature sizes are reduced (e.g., scaled to smaller sizes) to accommodate a greater density of features, and as features are fabricated at the base of openings with higher aspect ratios, precise and accurate fabrication of structure features—such as steps and the contact structures that extend thereto—may be more challenging and may lead to fabrication errors. These errors may include misalignments between a contact structure and its target step and/or electrical shorting between a contact structure and the conductive structure(s) of tiers other than that of its intended, target step. Accordingly, designing and fabricating 3D NAND memory devices continues to present challenges.

### BRIEF DESCRIPTION OF THE DRAWINGS

FIG. 1A is a simplified, partial perspective view of a microelectronic device structure at a processing stage of a method forming a microelectronic device, in accordance with embodiments of the disclosure. FIG. 1B is a simplified, longitudinal cross-sectional view of a portion A (identified with dashed lines in FIG. 1A) of the microelectronic device structure at the processing stage of FIG. 1A. FIG. 1C is a simplified, partial longitudinal cross-sectional view of a portion of the microelectronic device structure at the processing stage of FIGS. 1A and 1B about a dashed line B-B shown in FIG. 1B.

FIG. 2A is a simplified, longitudinal cross-sectional view of the portion A of the microelectronic device structure shown in FIGS. 1A through 1C at another processing stage of the method forming the microelectronic device following the processing stage of FIGS. 1A through 1C. FIG. 2B is a simplified, partial longitudinal cross-sectional view of a portion of the microelectronic device structure at the processing stage of FIG. 2A about the dashed line B-B shown in FIG. 2A.

FIG. 3A is a simplified, partial perspective view of a microelectronic device structure shown in FIGS. 1A through 1C at another processing stage of the method forming the microelectronic device following the processing stage of FIGS. 2A and 2B. FIG. 3B is a simplified, longitudinal cross-sectional view of the portion A of the microelectronic device structure shown at the processing stage of FIG. 3A. FIG. 3C is a simplified, partial longitudinal cross-sectional view of a portion of the microelectronic device structure at the processing stage of FIGS. 3A and 3B about the dashed line B-B shown in FIG. 3A. FIG. 3D is a simplified, partial longitudinal cross-sectional view of another portion of the microelectronic device structure at the processing stage of FIGS. 3A and 3B about the dashed line C-C shown in FIG. 3A.

FIG. 4A is a simplified, longitudinal cross-sectional view of the portion A of the microelectronic device structure shown in FIGS. 1A through 1C at another processing stage of the method forming the microelectronic device following the processing stage of FIGS. 3A through 3D. FIG. 4B is a simplified, partial longitudinal cross-sectional view of a portion of the microelectronic device structure at the processing stage of FIG. 4A about the dashed line B-B shown in FIG. 4A. FIG. 4C is a simplified, partial longitudinal cross-sectional view of another portion of the microelectronic device structure at the processing stage of FIG. 4A about the dashed line C-C shown in FIG. 4A.

FIG. 5A is a simplified, partial perspective view of a microelectronic device structure shown in FIGS. 1A through 1C at another processing stage of the method forming the microelectronic device following the processing stage of FIGS. 4A through 4C. FIG. 5B is a simplified, longitudinal cross-sectional view of the portion A of the microelectronic device structure shown at the processing stage of FIG. 5A. FIG. 5C is a simplified, partial longitudinal cross-sectional view of a portion of the microelectronic device structure at the processing stage of FIGS. 5A and 5B about the dashed line B-B shown in FIG. 5A. FIG. 5D is a simplified, partial longitudinal cross-sectional view of another portion of the microelectronic device structure at the processing stage of FIGS. 5A and 5B about the dashed line C-C shown in FIG. 5A.

FIG. 6A is a simplified, longitudinal cross-sectional view of the portion A of the microelectronic device structure shown in FIGS. 1A through 1C at another processing stage of the method forming the microelectronic device following the processing stage of FIGS. 5A through 5D. FIG. 6B is a simplified, partial longitudinal cross-sectional view of a portion of the microelectronic device structure at the processing stage of FIG. 6A about the dashed line B-B shown in FIG. 6A. FIG. 6C is a simplified, partial longitudinal cross-sectional view of another portion of the microelectronic device structure at the processing stage of FIG. 6A about the dashed line C-C shown in FIG. 6A.

FIG. 7A is a simplified, longitudinal cross-sectional view of the portion A of the microelectronic device structure shown in FIGS. 1A through 1C at another processing stage of the method forming the microelectronic device following the processing stage of FIGS. 6A through 6D. FIG. 7B is a simplified, partial longitudinal cross-sectional view of a portion of the microelectronic device structure at the processing stage of FIG. 7A about the dashed line B-B shown in FIG. 7A. FIG. 7C is a simplified, partial longitudinal cross-sectional view of another portion of the microelectronic device structure at the processing stage of FIG. 7A about the dashed line C-C shown in FIG. 7A.

FIG. 8 is a simplified partial cutaway perspective view of a microelectronic device, in accordance with embodiments of the disclosure.

FIG. 9 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessary limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, materials, structures, trenches, devices) described as “neighboring” one another means and includes features of the disclosed identity (or identities) that are located most proximate (e.g., closest to) one another. Additional features (e.g., additional regions, additional materials, additional structures, additional trenches, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “intersection” means and includes a location at which two or more features (e.g., regions, structures, materials, trenches, devices) or, alternatively, two or more portions of a single feature meet. For example, an intersection between a first feature extending in a first direction (e.g., an X-direction) and a second feature extending in a second direction (e.g., a Y-direction) different than the first direction may be the location at which the first feature and the second feature meet.

As used herein, spatially relative terms, such as “beneath,” “below,” “lower,” “bottom,” “above,” “upper,” “top,” “front,” “rear,” “let,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x”, “y”, and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x”, “y”, and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}ZnₓO), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

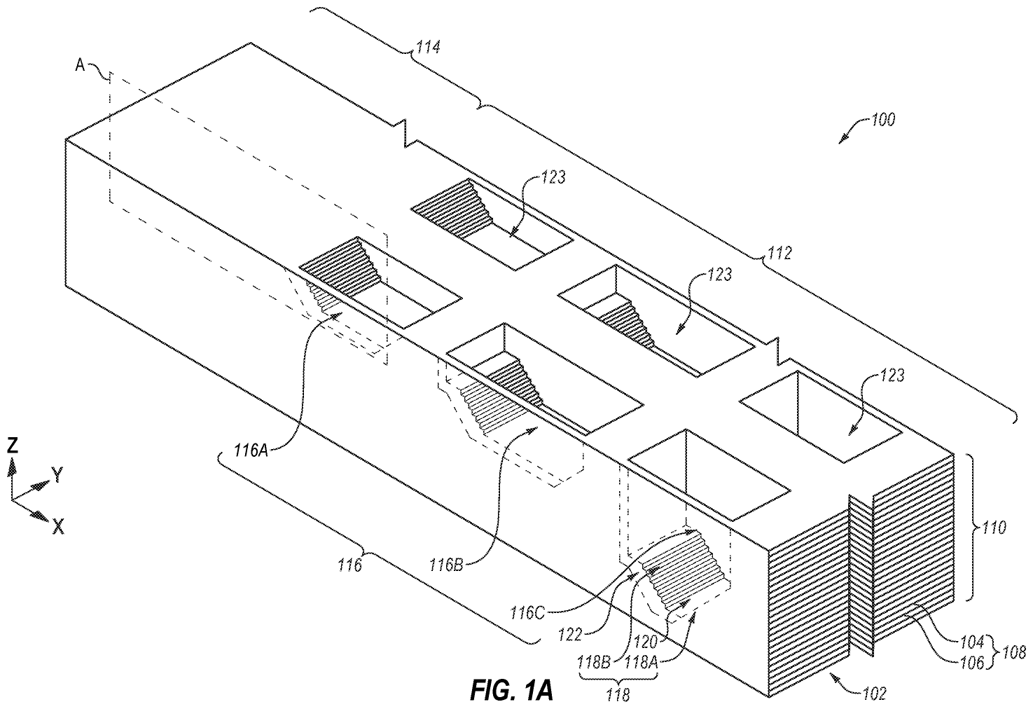

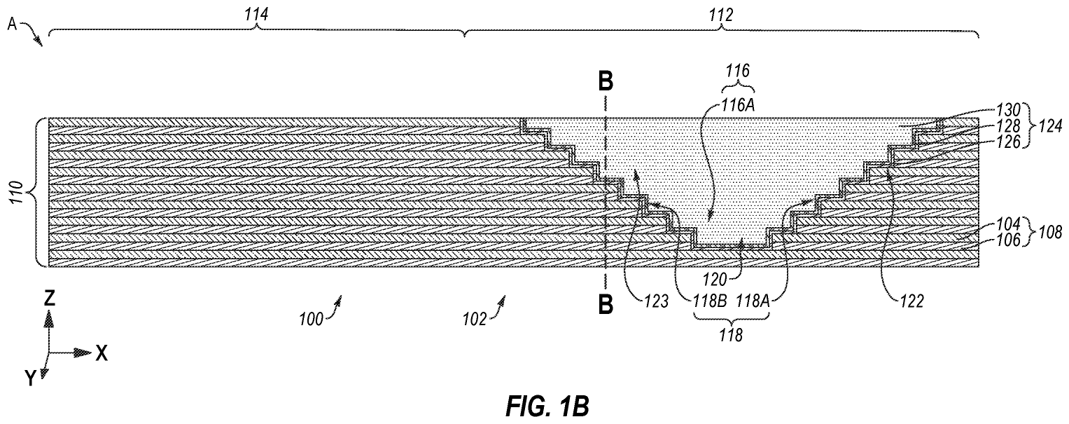

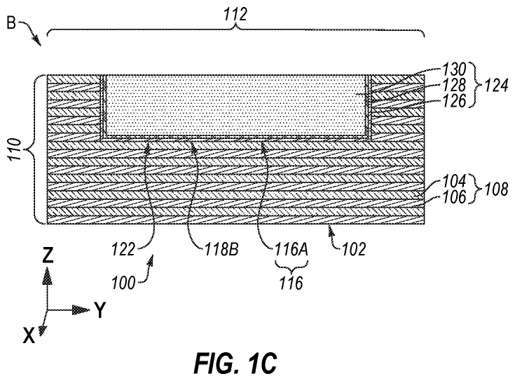

FIG. 1A through FIG. 7C are various views (described in further detail below) illustrating a microelectronic device structure at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device.

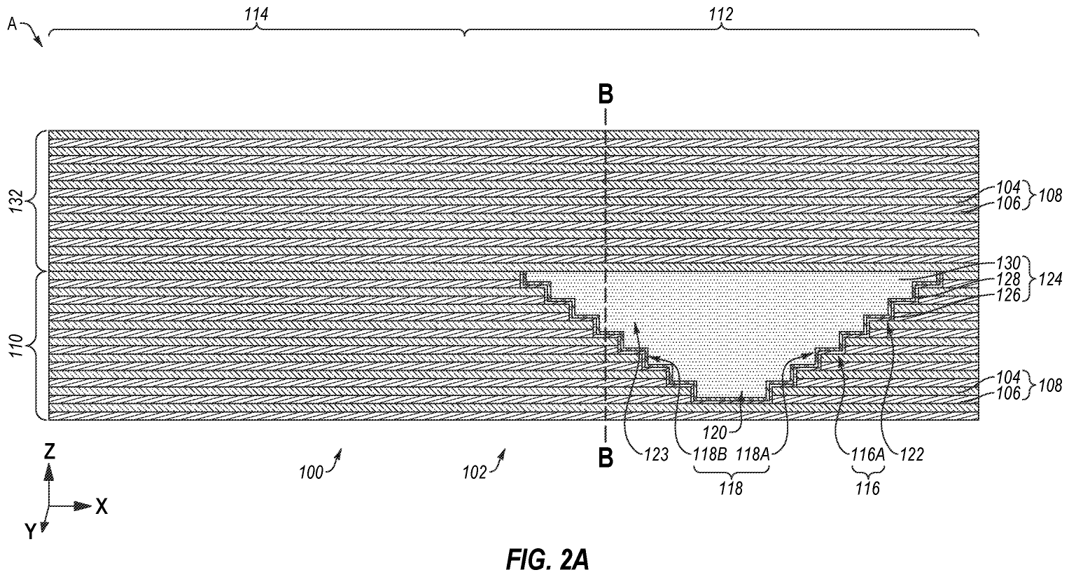

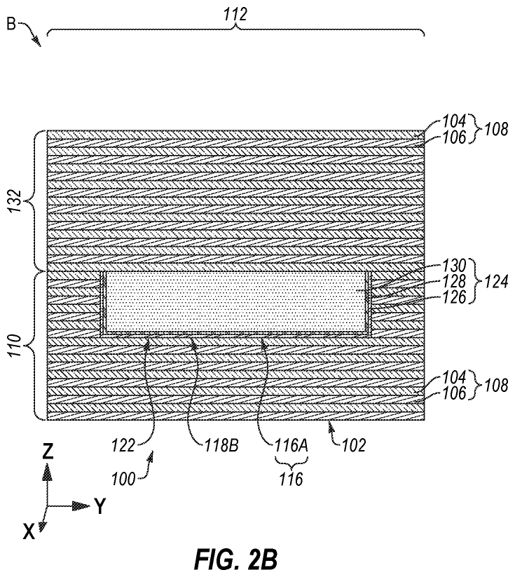

FIG. 1A depicts a simplified, partial perspective view of a microelectronic device structure 100. As shown in FIG. 1A, the microelectronic device structure 100 may be formed to include a preliminary stack structure 102 including a vertically alternating (e.g., in a Z-direction) sequence of insulative material 104 and sacrificial material 106 arranged in tiers 108. Each of the tiers 108 of the preliminary stack structure 102 may individually include the sacrificial material 106 vertically neighboring (e.g., directly vertically adjacent) the insulative material 104. The tiers 108 of the preliminary stack structure 102 depicted in FIG. 1A may form a lower section 110 of preliminary stack structure 102. Additional tiers 108 may subsequently be formed over the lower section 110 of the preliminary stack structure 102 to form an upper section of the preliminary stack structure 102, as described in further detail below with reference to FIGS. 2A and 2B. In addition, the preliminary stack structure 102 may include a first stadium region 112 including lower stadium structures 116 within a horizontal area thereof, and a second stadium region 114 horizontally neighboring (e.g., in an X-direction) the first stadium region 112 and to subsequently include upper stadium structures within a horizontal area thereof. FIG. 1B is a simplified, longitudinal cross-sectional view of a portion A (identified with a dashed box in FIG. 1A) of the microelectronic device structure 100 at the processing stage depicted in FIG. 1A. FIG. 1C is a simplified, partial longitudinal cross-sectional view of a portion of the microelectronic device structure 100 at the processing stage of FIGS. 1A and 1B about a dashed line B-B shown in FIG. 1B.

The insulative material 104 of each of the tiers 108 of the preliminary stack structure 102 may be formed of and include at least one dielectric material, such one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 104 of each of the tiers 108 of the preliminary stack structure 102 is formed of and includes a dielectric oxide material, such as SiOₓ (e.g., SiO₂). The insulative material 104 of each of the tiers 108 may be substantially homogeneous, or the insulative material 104 of one or more (e.g., each) of the tiers 108 may be heterogeneous.

The sacrificial material 106 of each of the tiers 108 of the preliminary stack structure 102 may be formed of and include at least one material (e.g., at least one insulative material) that may be selectively removed relative to the insulative material 104. The sacrificial material 106 may be selectively etchable relative to the insulative material 104 during common (e.g., collective, mutual) exposure to a first etchant; and the insulative material 104 may be selectively etchable to the sacrificial material 106 during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. By way of non-limiting example, depending on the material composition of the insulative material 104, the sacrificial material 106 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductor material (e.g., polycrystalline silicon). In some embodiments, the sacrificial material 106 of each of the tiers 108 of the preliminary stack structure 102 is formed of and includes a dielectric nitride material, such as SiN_{y} (e.g., Si₃N₄). The sacrificial material 106 may, for example, be selectively etchable relative to the insulative material 104 during common exposure to a wet etchant comprising phosphoric acid (H₃PO₄).

The lower section 110 of the preliminary stack structure 102 may be formed to include any desired quantity of the tiers 108. A quantity of the tiers 108 forming in the lower section 110 may be selected at least partially based on a total quantity of the tiers 108 desired following the subsequent formation of an upper section of the preliminary stack structure 102 over the lower section 110, as described in further detail below with reference to FIGS. 2A and 2B. By way of non-limiting example, the lower section 110 of the preliminary stack structure 102 and the subsequently formed upper section of the preliminary stack structure 102 may together be formed include greater than or equal to sixteen (16) of the tiers 108, such as greater than or equal to thirty-two (32) of the tiers 108, greater than or equal to sixty-four (64) of the tiers 108, greater than or equal to one hundred and twenty-eight (128) of the tiers 108, or greater than or equal to two hundred and fifty-six (256) of the tiers 108. In some embodiments, the lower section 110 of the preliminary stack structure 102 is formed to include a greater quantity of the tiers 108 than the subsequently formed upper section of the preliminary stack structure 102.

As shown in FIG. 1A, within a horizontal area of the first stadium region 112, the lower section 110 of the preliminary stack structure 102 may include a desired distribution of the lower stadium structures 116. As shown in FIG. 1A, the first stadium region 112 of the preliminary stack structure 102 may include rows of the lower stadium structures 116 extending in parallel in a X-direction, and columns of the lower stadium structures 116 extending in a Y-direction orthogonal to the X-direction. The rows of the lower stadium structures 116 may individually include some of the lower stadium structures 116 at least partially (e.g., substantially) aligned with one another in the Y-direction. The columns of the of the lower stadium structures 116 may individually include other of the lower stadium structures 116 at least partially (e.g., substantially) aligned with one another in the X-direction. Different rows of the lower stadium structures 116 may be positioned within different horizontal areas of the preliminary stack structure 102 to be formed into different blocks of a stack structure to be formed from the preliminary stack structure 102, as described in further detail below. In FIG. 1A, for clarity and ease of understanding the drawings and associated description, portions of the preliminary stack structure 102 are depicted as transparent to more clearly show some of the lower stadium structures 116 distributed within the first stadium region 112 of the preliminary stack structure 102.

Still referring to FIG. 1A, at least some (e.g., each) of the lower stadium structures 116 within an individual row of the lower stadium structures 116 may be positioned at different vertical elevations in the Z-direction than one another. For example, as depicted in FIG. 1A, an individual row of the lower stadium structures 116 may include a first lower stadium structure 116A, a second lower stadium structure 116B at a relatively lower vertical position (e.g., in the Z-direction) within the preliminary stack structure 102 than the first lower stadium structure 116A, and a third lower stadium structure 116C at a relatively lower vertical position within the preliminary stack structure 102 than the second lower stadium structure 116B. Each lower stadium structure 116 within an individual row of the lower stadium structures 116 may be formed to be located at a different vertical elevation within the lower section 110 of the preliminary stack structure 102 than each other lower stadium structure 116 within the individual row of the lower stadium structures 116. In addition, in some embodiments, within an individual row of the lower stadium structures 116, horizontally neighboring (e.g., in the X-direction) lower stadium structures 116 are substantially uniformly (e.g., equally, evenly) horizontally spaced apart from one another.

In additional embodiments, one or more rows of the lower stadium structures 116 may individually include a different quantity of lower stadium structures 116 and/or a different distribution of lower stadium structures 116 than that depicted in FIG. 1A. For example, an individual row of the lower stadium structures 116 may include greater than three (3) of the lower stadium structures 116 (e.g., greater than or equal to four (4) of the lower stadium structures 116, greater than or equal to five (5) of the lower stadium structures 116, greater than or equal to ten (10) of the lower stadium structures 116, greater than or equal to twenty-five (25) of the lower stadium structures 116, greater than or equal to fifty (50) of lower stadium structures 116), or less than three (3) of the lower stadium structures 116 (e.g., less than or equal to two (2) of the lower stadium structures 116, only one (1) of the lower stadium structures 116). As another example, within an individual row of the lower stadium structures 116, at least some horizontally neighboring lower stadium structures 116 may be at least partially non-uniformly (e.g., non-equally, non-evenly) horizontally spaced, such that at least one of the lower stadium structures 116 of the row is separated from at least two other of the lower stadium structures 116 of the row horizontally neighboring the at least one lower stadium structures 116 by different (e.g., non-equal) distances. As an additional non-limiting example, within an individual row of the lower stadium structures 116, vertical positions (e.g., in the Z-direction) of the lower stadium structures 116 may vary in a different manner (e.g., may alternate between relatively deeper and relatively shallower vertical positions) than that depicted in FIG. 1A.

Each of the lower stadium structures 116 may individually include opposing staircase structures 118, and a central region 120 horizontally interposed between (e.g., in the X-direction) the opposing staircase structures 118. The opposing staircase structures 118 of each lower stadium structure 116 may include a forward staircase structure 118A and a reverse staircase structure 118B. A phantom line extending from a top of the forward staircase structure 118A to a bottom of the forward staircase structure 118A may have a positive slope, and another phantom line extending from a top of the reverse staircase structure 118B to a bottom of the reverse staircase structure 118B may have a negative slope. As shown in FIG. 1A, the forward staircase structure 118A and the reverse staircase structure 118B of an individual lower stadium structure 116 may be positioned at substantially the same vertical position as one another, and may exhibit topographic profiles substantially mirroring one another.

In additional embodiments, one or more of the lower stadium structures 116 individually exhibits a different configuration than that depicted in FIG. 1A. As a non-limiting example, at least one lower stadium structure 116 may be modified to include a forward staircase structure 118A but not a reverse staircase structure 118B (e.g., the reverse staircase structure 118B may be absent), or at least one lower stadium structure 116 may be modified to include a reverse staircase structure 118B but not a forward staircase structure 118A (e.g., the forward staircase structure 118A may be absent). In such embodiments, the central region 120 horizontally neighbors a bottom of the forward staircase structure 118A (e.g., if the reverse staircase structure 118B is absent), or the central region 120 horizontally neighbors a bottom of the reverse staircase structure 118B (e.g., if the forward staircase structure 118A is absent). As another non-limiting example, at least one lower stadium structure 116 may be modified such that the forward staircase structure 118A thereof is at least partially (e.g., completely) vertically offset (e.g., in the Z-direction) from the reverse staircase structure 118B thereof. For example, the forward staircase structure 118A of an individual lower stadium structure 116 may vertically underlie the reverse staircase structure 118B of the lower stadium structure 116, such that an uppermost boundary of the forward staircase structure 118A is at or below a lowermost boundary of the reverse staircase structure 118B; or the reverse staircase structure 118B of an individual lower stadium structure 116 may vertically underlie the forward staircase structure 118A of the lower stadium structure 116, such that an uppermost boundary of the reverse staircase structure 118B is at or below a lowermost boundary of the forward staircase structure 118A. In such embodiments, the central region 120 of the lower stadium structure 116 has a first portion horizontally neighboring a bottom of one of the forward staircase structure 118A and the reverse staircase structure 118B; and a second portion vertically offset from the first portion and horizontally neighboring a bottom of the other of the forward staircase structure 118A and the reverse staircase structure 118B.

The opposing staircase structures 118 (e.g., the forward staircase structure 118A and the reverse staircase structure 118B) of an individual lower stadium structure 116 each include steps 122 defined by edges (e.g., horizontal ends) of the tiers 108 of the preliminary stack structure 102. For the opposing staircase structures 118 of an individual lower stadium structure 116, each step 122 of the forward staircase structure 118A may have a counterpart step 122 within the reverse staircase structure 118B having substantially the same geometric configuration (e.g., shape, dimensions), vertical position (e.g., in the Z-direction), and horizontal distance (e.g., in the X-direction) from a horizontal center (e.g., in the X-direction) of the central region 120 of the lower stadium structure 116. In additional embodiments, at least one step 122 of the forward staircase structure 118A does not have a counterpart step 122 within the reverse staircase structure 118B having substantially the same geometric configuration (e.g., shape, dimensions), vertical position (e.g., in the Z-direction), and/or horizontal distance (e.g., in the X-direction) from horizontal center (e.g., in the X-direction) of the central region 120 of the lower stadium structure 116; and/or at least one step 122 of the reverse staircase structure 118B does not have a counterpart step 122 within the forward staircase structure 118A having substantially the same geometric configuration (e.g., shape, dimensions), vertical position (e.g., in the Z-direction), and/or horizontal distance (e.g., in the X-direction) from horizontal center (e.g., in the X-direction) of the central region 120 of the lower stadium structure 116.

Each of the lower stadium structures 116 of the preliminary stack structure 102 may individually include a desired quantity of steps 122. Each of the lower stadium structures 116 may include substantially the same quantity of steps 122 as each other of the lower stadium structures 116, or at least one of the lower stadium structures 116 may include a different quantity of steps 122 than at least one other of the lower stadium structures 116. In some embodiments, at least one of the lower stadium structures 116 includes a different (e.g., greater, lower) quantity of steps 122 than at least one other of the lower stadium structures 116. As shown in FIG. 1A, in some embodiments, the steps 122 of each of the lower stadium structures 116 are arranged in order, such that steps 122 directly horizontally adjacent (e.g., in the X-direction) one another correspond to tiers 108 of the preliminary stack structure 102 directly vertically adjacent (e.g., in the Z-direction) one another. In additional embodiments, the steps 122 of at least one of the lower stadium structures 116 are arranged out of order, such that at least some steps 122 of the lower stadium structure 116 directly horizontally adjacent (e.g., in the X-direction) one another correspond to tiers 108 of preliminary stack structure 102 not directly vertically adjacent (e.g., in the Z-direction) one another.

With continued reference to FIG. 1A, for an individual lower stadium structure 116, the central region 120 thereof may horizontally intervene (e.g., in the X-direction) between and separate the forward staircase structure 118A thereof from the reverse staircase structure 118B thereof. The central region 120 may horizontally neighbor a vertically lowermost step 122 of the forward staircase structure 118A, and may also horizontally neighbor a vertically lowermost step 122 of the reverse staircase structure 118B. The central region 120 of an individual lower stadium structure 116 may have desired horizontal dimensions. In addition, the central region 120 of each of the lower stadium structures 116 may have substantially the same horizontal dimensions as the central region 120 of each other of the lower stadium structures 116, or the central region 120 of at least one of the lower stadium structures 116 may have different horizontal dimensions than the central region 120 of at least one other of the lower stadium structures 116.

Still referring to FIG. 1A, each lower stadium structure 116 (including the forward staircase structure 118A, the reverse staircase structure 118B, and the central region 120 thereof) within the preliminary stack structure 102 may individually partially define boundaries (e.g., horizontal boundaries, vertical boundaries) of a first filled trench 123 vertically extending (e.g., in the Z-direction) through the preliminary stack structure 102. The portions of the preliminary stack structure 102 horizontally neighboring an individual lower stadium structure 116 may also partially define the boundaries of the first filled trench 123 associated with the lower stadium structure 116. The first filled trench 123 may only vertically extend through tiers 108 of the preliminary stack structure 102 defining the forward staircase structure 118A and the reverse staircase structure 118B of the lower stadium structure 116; or may also vertically extend through additional tiers 108 of the preliminary stack structure 102 not defining the forward staircase structure 118A and the reverse staircase structure 118B of the lower stadium structure 116, such as additional tiers 108 within the lower section 110 of the preliminary stack structure 102 and vertically overlying the lower stadium structure 116. Edges of the additional tiers 108 of the preliminary stack structure 102 may, for example, define one or more additional stadium structures vertically overlying and horizontally offset from the lower stadium structure 116. In FIG. 1A, for clarity and ease of understanding the drawings and associated description, the first filled trenches 123 are depicted as transparent to more clearly show some of the lower stadium structures 116 distributed within the first stadium region 112 of the preliminary stack structure 102. However, the first filled trenches 123 are individually filled with multiple (e.g., more than one, a plurality of) dielectric materials, as described in further detail below.

As previously described, FIG. 1B is a simplified, longitudinal cross-sectional view of portion A (identified with a dashed box in FIG. 1A) of the microelectronic device structure 100 at the processing stage depicted in FIG. 1A. The portion A encompasses the first lower stadium structure 116A of an individual row of the lower stadium structures 116 within the first stadium region 112 of the preliminary stack structure 102. The portion A also encompasses part of the second stadium region 114 of the preliminary stack structure 102 horizontally neighboring (e.g., in the X-direction) the first lower stadium structure 116A of the individual row of the lower stadium structures 116. While additional features (e.g., structures, materials) of the microelectronic device structure 100 are described hereinbelow with reference to the portion A of the microelectronic device structure 100, such additional features may also be formed and included in additional portions of the microelectronic device structure 100, including additional portions of the first stadium region 112 of the preliminary stack structure 102 (FIG. 1A) encompassing other of the lower stadium structures 116 and additional portions of the first stadium region 112 of the preliminary stack structure 102 (FIG. 1A) having boundaries defined by the other of the lower stadium structures 116.

Referring to FIG. 1B, the first filled trenches 123 may individually include dielectric fill materials 124 within boundaries (e.g., vertical boundaries, horizontal boundaries) thereof. For example, as shown in FIG. 1B, the dielectric fill materials 124 within each first filled trench 123 may include a first dielectric material 126 (e.g., a first dielectric liner material), a second dielectric material 128 (e.g., a second dielectric liner material), and a third dielectric material 130 (e.g., a dielectric fill material). For an individual first filled trench 123, the first dielectric material 126 may be formed on or over surfaces (e.g., horizontally extending surfaces, vertically extending surfaces) of the preliminary stack structure 102 defining boundaries (e.g., horizontal boundaries, vertical boundaries) of the first filled trench 123; the second dielectric material 128 may be formed on or over the first dielectric material 126; and the third dielectric material 130 may be formed on or over the second dielectric material 128. As shown in FIG. 1B, uppermost boundaries (e.g., uppermost surfaces) of individual first filled trenches 123 (including uppermost surfaces of the first dielectric material 126, the second dielectric material 128, and the third dielectric material 130) may be formed to be substantially coplanar with an uppermost boundary (e.g., an uppermost surface) of the lower section 110 of the preliminary stack structure 102.

The first dielectric material 126 may be employed (e.g., serve) as a barrier material to protect (e.g., mask) the second dielectric material 128 from removal during subsequent processing acts (e.g., subsequent replacement gate processing acts, such as subsequent etching acts), as described in further detail below. The first dielectric material 126 may be formed to have a desired thickness capable of protecting the second dielectric material 128 during the subsequent processing acts. For an individual first filled trench 123, the first dielectric material 126 and thereof may be formed to substantially continuously extend on or over surfaces of the preliminary stack structure 102 defining an individual lower stadium structure 116 underlying the individual first filled trench 123, as well as on or over additional surfaces of the preliminary stack structure 102 neighboring (e.g., vertically neighboring, horizontally neighboring) the individual lower stadium structure 116. The first dielectric material 126 forming a portion of an individual first filled trench 123 may be substantially confined within boundaries (e.g., vertical boundaries, horizontal boundaries) of the individual first filled trench 123.

The first dielectric material 126 may be formed of and include at least one dielectric material having different etch selectivity than the sacrificial material 106 of the tiers 108 of the preliminary stack structure 102. The first dielectric material 126 may also have different etch selectivity than the second dielectric material 128. The first dielectric material 126 may, for example, have etch selectively substantially similar to that of the insulative material 104 of the tiers 108 of the preliminary stack structure 102. By way of non-limiting example, the first dielectric material 126 may be formed of and include at least one oxygen-containing dielectric material, such as a one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric oxynitride material (e.g., SiOₓN_{y}), and at least one dielectric carboxynitride material (e.g., SiOₓC_{z}N_{y}). In some embodiments, the first dielectric material 126 is formed of and includes SiOₓ (e.g., SiO₂).

The second dielectric material 128 may be employed (e.g., serve) as an etch stop material during subsequent processing acts (e.g., subsequent etching acts) to form openings (e.g., contact openings, contact vias) vertically extending through the third dielectric material 130, as described in further detail below. The second dielectric material 128 thereof may be formed to have a desired thickness capable of protecting the first dielectric material 126 underlying the second dielectric material 128 from removal during the subsequent processing acts. For an individual first filled trench 123, the second dielectric material 128 thereof may be formed to substantially continuously extend on or over the first dielectric material 126. The second dielectric material 128 forming a portion of an individual first filled trench 123 may be substantially confined within boundaries (e.g., vertical boundaries, horizontal boundaries) of the individual first filled trench 123.

The second dielectric material 128 may be formed of and include at least one dielectric material having different etch selectivity than the third dielectric material 130. The second dielectric material 128 may also have different etch selectivity than the first dielectric material 126. The second dielectric material 128 may, for example, have etch selectively substantially similar to that of the sacrificial material 106 of the tiers 108 of the preliminary stack structure 102. By way of non-limiting example, the second dielectric material 128 may be formed of and include at least one nitrogen-containing dielectric material, such as at least one dielectric nitride material. In some embodiments, the second dielectric material 128 is formed of and includes SiN_{y} (e.g., Si₃N₄).

Still referring to FIG. 1B, the third dielectric material 130 may substantially fill portions of the first filled trenches 123 unoccupied by the first dielectric material 126 and the second dielectric material 128. For an individual first filled trench 123, the third dielectric material 130 thereof may be formed to substantially continuously extend on or over the second dielectric material 128. The third dielectric material 130 may be formed to exhibit a substantially planar upper vertical boundary, and a substantially non-planar lower vertical boundary complementary to (e.g., substantially mirroring) a topography thereunder.

The third dielectric material 130 may be formed of and include at least one dielectric material having different etch selectivity than the second dielectric material 128. The third dielectric material 130 may, for example, have etch selectively substantially similar to that of one or more of the first dielectric material 126 and the insulative material 104 of the tiers 108 of the preliminary stack structure 102. By way of non-limiting example, the third dielectric material 130 may be formed of and include at least one oxygen-containing dielectric material, such as a one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric oxynitride material (e.g., SiOₓN_{y}), and at least one dielectric carboxynitride material (e.g., SiOₓC_{z}N_{y}). In some embodiments, the third dielectric material 130 is formed of and includes SiOₓ (e.g., SiO₂).

As previously described, FIG. 1C is a simplified, partial longitudinal cross-sectional view of a portion of the microelectronic device structure 100 at the processing stage of FIGS. 1A and 1B about the dashed line B-B shown in FIG. 1B. As shown in FIG. 1C, the insulative material 104 and the sacrificial material 106 of each tier 108 of the preliminary stack structure 102 having horizontal ends defining an individual lower stadium structure 116 (e.g., the first lower stadium structure 116A) within the preliminary stack structure 102 may continuously horizontally extend in the X-direction across sides of the lower stadium structure 116 opposing one another in the Y-direction. In addition, for an individual lower stadium structure 116 within the preliminary stack structure 102, inner horizontal boundaries (e.g., inner sidewalls) of the preliminary stack structure 102 partially defining the first filled trench 123 associated with (e.g., vertically overlying and within horizontal boundaries of) the lower stadium structure 116 may be oriented substantially perpendicular to the uppermost vertical boundary (e.g., the uppermost surface) of the lower section 110 of the preliminary stack structure 102, or may be oriented substantially non-perpendicular to the uppermost vertical boundary (e.g., uppermost surface) of the lower section 110 of the preliminary stack structure 102.

Referring next to FIG. 2A, which is a simplified, longitudinal cross-sectional view of the portion A of the microelectronic device structure 100 following the processing stage previously described with reference to FIGS. 1A through 1D, an additional quantity of the tiers 108 of the insulative material 104 and the sacrificial material 106 may be formed on or over the lower section 110 of the preliminary stack structure 102 to form an upper section 132 of the preliminary stack structure 102. FIG. 2B is a simplified, partial longitudinal cross-sectional view of a portion of the microelectronic device structure 100 at the processing stage of FIG. 2A about the dashed line B-B shown in FIG. 2A.

The upper section 132 of the preliminary stack structure 102 is formed to vertically overlie (e.g., in the Z-direction) the lower section 110 of the preliminary stack structure 102. The formation of the upper section 132 of the preliminary stack structure 102 increases an overall vertical height of the preliminary stack structure 102, and increases an overall quantity of the tiers 108 of the insulative material 104 and the sacrificial material 106 included in the preliminary stack structure 102. As described in further detail below, additional stadium structures may subsequently be formed within the upper section 132 of the preliminary stack structure 102, and may vertically overlie the lower stadium structures 116 within the lower section 110 of the preliminary stack structure 102.

As shown in FIG. 2A, the upper section 132 of the preliminary stack structure 102 may be formed to substantially continuously horizontally extend (e.g., in the X-direction, in the Y-direction) over the lower section 110 of the preliminary stack structure 102. The upper section 132 of the preliminary stack structure 102 may substantially horizontally extend across the first stadium region 112 and the second stadium region 114 of the preliminary stack structure 102. Tiers 108 of the insulative material 104 and the sacrificial material 106 formed within vertical boundaries of the upper section 132 of the preliminary stack structure 102 may substantially horizontally extend across and cover the lower stadium structures 116 and the first filled trenches 123 positioned within the vertical boundaries of the lower section 110 of the preliminary stack structure 102. In addition, the tiers 108 of the insulative material 104 and the sacrificial material 106 formed within vertical boundaries of the upper section 132 of the preliminary stack structure 102 may substantially horizontally extend across and cover horizontal areas of the lower section 110 of the preliminary stack structure 102 positioned outside of horizontal boundaries (e.g., outside of horizontal areas) of the lower stadium structures 116 and the first filled trenches 123.

The upper section 132 of the preliminary stack structure 102 may be formed to include any desired quantity of the tiers 108. By way of non-limiting example, the upper section 132 of the preliminary stack structure 102 may be formed to include greater than or equal to four (4) of the tiers 108, such as greater than or equal to six (6) of the tiers 108, greater than or equal to eight (8) of the tiers 108, or greater than or equal to sixteen (16) of the tiers 108.

In some embodiments, within the upper section 132 of the preliminary stack structure 102, a sequence of the insulative material 104 vertically alternating with the sacrificial material 106 is formed to begin with the insulative material 104. The insulative material 104 of a lowest tier 108 within the upper section 132 of the preliminary stack structure 102 may be formed on an uppermost surface of the insulative material 104 of a highest tier 108 within the lower section 110 of the preliminary stack structure 102, and may also be formed on uppermost surfaces of the dielectric fill materials 124 (e.g., the first dielectric material 126, the second dielectric material 128, the third dielectric material 130) of the first filled trenches 123. In additional embodiments, within the upper section 132 of the preliminary stack structure 102, a sequence of the insulative material 104 vertically alternating with the sacrificial material 106 is formed to begin with the sacrificial material 106. In some such embodiments, the sacrificial material 106 of a lowest tier 108 within the upper section 132 of the preliminary stack structure 102 is formed on an uppermost surface of the insulative material 104 of a highest tier 108 within the lower section 110 of the preliminary stack structure 102, and is also formed on uppermost surfaces of the dielectric fill materials 124 of the first filled trenches 123 within the vertical boundaries of the lower section 10 of the preliminary stack structure 102.

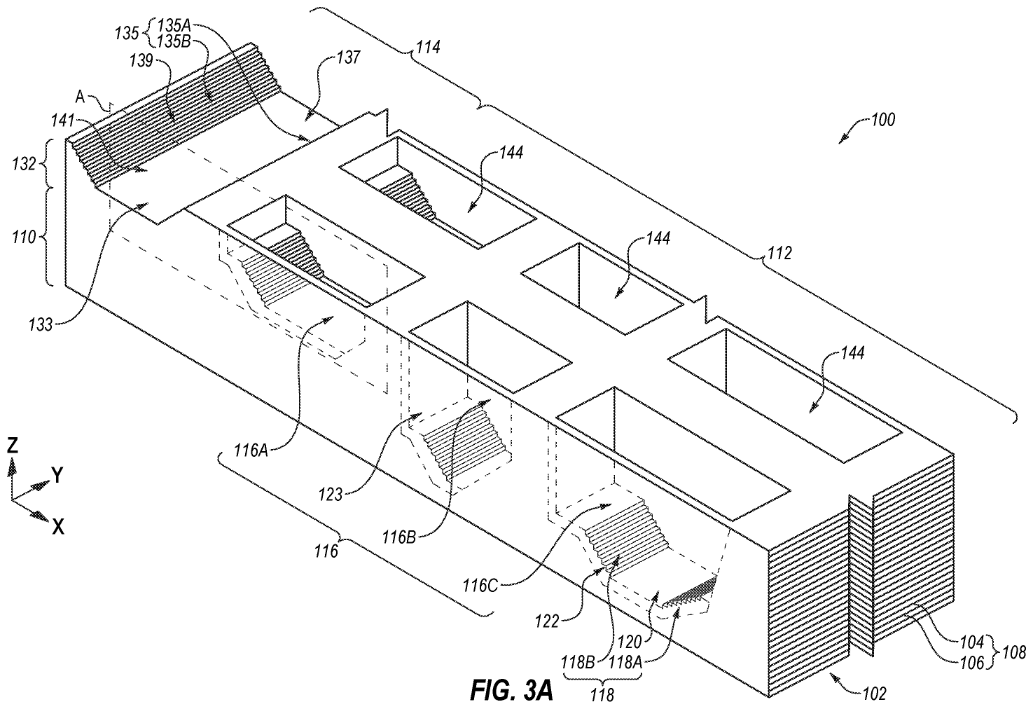

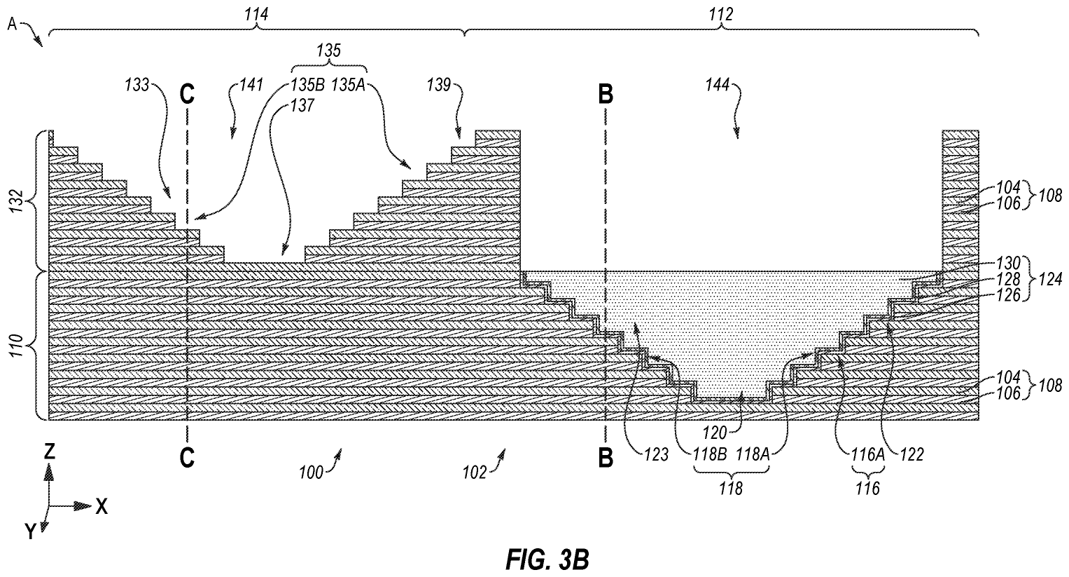

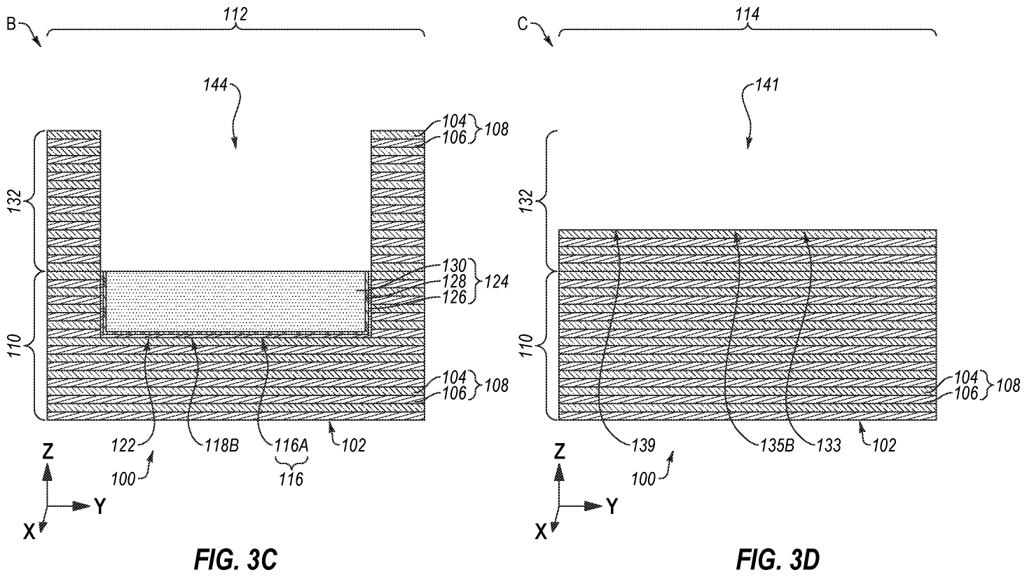

Referring next to FIG. 3A, which depicts a simplified, partial perspective view of the microelectronic device structure 100 following the processing stage previously described with reference to FIGS. 2A and 2B, a preliminary upper stadium structure 133 may be formed within the upper section 132 of the preliminary stack structure 102. The preliminary upper stadium structure 133 may be formed within horizontal boundaries (e.g., within a horizontal area) of the second stadium region 114 of the preliminary stack structure 102. In addition, as shown in FIG. 3A, portions of the upper section 132 of the preliminary stack structure 102 within the horizontal boundaries of the first stadium region 112 of the preliminary stack structure 102 may be removed to expose the first filled trenches 123 overlying the lower stadium structures 116 within the lower section 110 of the preliminary stack structure 102. FIG. 3B is a simplified, longitudinal cross-sectional view of the portion A (identified with a dashed box in FIG. 3A) of the microelectronic device structure 100 at the processing stage depicted in FIG. 3A. FIG. 3C is a simplified, partial longitudinal cross-sectional view of a portion of the microelectronic device structure 100 at the processing stage of FIGS. 3A and 3B about the dashed line B-B shown in FIG. 3B. FIG. 3D is a simplified, partial longitudinal cross-sectional view of an additional portion of the microelectronic device structure 100 at the processing stage of FIGS. 3A and 3B about an additional dashed line C-C shown in FIG. 3B.

As shown in FIG. 3A, a horizontal dimension (e.g., horizontal width) in the Y-direction of the preliminary upper stadium structure 133 may be greater than the horizontal dimension in the Y-direction of an individual lower stadium structure 116 (e.g., the first lower stadium structure 116A). The horizontal dimension in the Y-direction of the preliminary upper stadium structure 133 may, for example, be greater than or equal to horizontal dimensions in the Y-direction of multiple (e.g., all) lower stadium structures 116 within a column of the lower stadium structures 116 extending in the Y-direction. The preliminary upper stadium structure 133 may horizontally extend substantially continuously in the Y-direction at least across a distance occupied by multiple (e.g., all) lower stadium structures 116 of a column of the lower stadium structures 116, as well as portions of the preliminary stack structure 102 horizontally interposed between horizontally neighboring lower stadium structures 116 of the column. The preliminary upper stadium structure 133 may be considered a “non-segmented” stadium structure since portions of the preliminary stack structure 102 do not disrupt the continuity of the preliminary upper stadium structure 133 in the Y-direction. Conversely, the lower stadium structures 116 may be considered “segmented” stadium structures since portions of the preliminary stack structure 102 intervene between lower stadium structures 116 aligned with one another in the X-direction and horizontally neighboring one another in the Y-direction.

Referring collectively to FIGS. 3A and 3B, the preliminary upper stadium structure 133 may be formed to include preliminary opposing staircase structures 135, and a preliminary central region 137 horizontally interposed between (e.g., in the X-direction) the preliminary opposing staircase structures 135. The preliminary opposing staircase structures 135 of the preliminary upper stadium structure 133 may include a preliminary forward staircase structure 135A and a preliminary reverse staircase structure 135B. A phantom line extending from a top of the preliminary forward staircase structure 135A to a bottom of the preliminary forward staircase structure 135A may have positive slope, and another phantom line extending from a top of the preliminary reverse staircase structure 135B to a bottom of the preliminary reverse staircase structure 135B may have negative slope. As shown in FIGS. 3A and 3B, the preliminary forward staircase structure 135A and the preliminary reverse staircase structure 135B of the preliminary upper stadium structure 133 may be positioned at substantially the same vertical position as one another, and may exhibit topographic profiles substantially mirroring one another.

In additional embodiments, the preliminary upper stadium structure 133 is formed to exhibit a different configuration than that depicted in FIG. 3A. As a non-limiting example, the preliminary upper stadium structure 133 may be modified to include a preliminary forward staircase structure 135A but not a preliminary reverse staircase structure 135B (e.g., the preliminary reverse staircase structure 135B may be absent); or the preliminary upper stadium structure 133 may be modified to include the preliminary reverse staircase structure 135B but not a preliminary forward staircase structure 135A (e.g., the preliminary forward staircase structure 135A may be absent). In such embodiments, the preliminary central region 137 horizontally neighbors a bottom of the preliminary forward staircase structure 135A (e.g., if the preliminary reverse staircase structure 135B is absent), or the preliminary central region 137 horizontally neighbors a bottom of the preliminary reverse staircase structure 135B (e.g., if the preliminary forward staircase structure 135A is absent). As another non-limiting example, the preliminary forward staircase structure 135A may be at least partially (e.g., completely) vertically offset (e.g., in the Z-direction) from the preliminary reverse staircase structure 135B. For example, the preliminary forward staircase structure 135A may vertically underlie the preliminary reverse staircase structure 135B, such that an uppermost boundary of the preliminary forward staircase structure 135A is at or below a lowermost boundary of the preliminary reverse staircase structure 135B; or the preliminary reverse staircase structure 135B may vertically underlie the preliminary forward staircase structure 135A, such that an uppermost boundary of the preliminary reverse staircase structure 135B is at or below a lowermost boundary of the preliminary forward staircase structure 135A. In such embodiments, the preliminary central region 137 has a first portion horizontally neighboring a bottom of one of the preliminary forward staircase structure 135A and the preliminary reverse staircase structure 135B; and a second portion vertically offset from the first portion and horizontally neighboring a bottom of the other of the preliminary forward staircase structure 135A and the preliminary reverse staircase structure 135B.

The preliminary opposing staircase structures 135 (e.g., the preliminary forward staircase structure 135A and the preliminary reverse staircase structure 135B) of the preliminary upper stadium structure 133 may be formed to include preliminary steps 139 defined by edges (e.g., horizontal ends) of the tiers 108 of the upper section 132 of the preliminary stack structure 102. Each preliminary step 139 of the preliminary forward staircase structure 135A may have a counterpart preliminary step 139 within the preliminary reverse staircase structure 135B having substantially the same geometric configuration (e.g., shape, dimensions), vertical position (e.g., in the Z-direction), and horizontal distance (e.g., in the X-direction) from a horizontal center (e.g., in the X-direction) of the preliminary central region 137 of the preliminary upper stadium structure 133. In additional embodiments, at least one preliminary step 139 of the preliminary forward staircase structure 135A does not have a counterpart preliminary step 139 within the preliminary reverse staircase structure 135B having substantially the same geometric configuration (e.g., shape, dimensions), vertical position (e.g., in the Z-direction), and/or horizontal distance (e.g., in the X-direction) from the horizontal center (e.g., in the X-direction) of the preliminary central region 137 of the preliminary upper stadium structure 133; and/or at least one preliminary step 139 of the preliminary reverse staircase structure 135B does not have a counterpart preliminary step 139 within the preliminary forward staircase structure 135A having substantially the same geometric configuration (e.g., shape, dimensions), vertical position (e.g., in the Z-direction), and/or horizontal distance (e.g., in the X-direction) from horizontal center (e.g., in the X-direction) of the preliminary central region 137 of the preliminary upper stadium structure 133.

As shown in FIG. 3A, a horizontal dimension (e.g., horizontal width) in the Y-direction of the preliminary steps 139 of the preliminary upper stadium structure 133 may be greater than the horizontal dimension in the Y-direction of the steps 122 of an individual lower stadium structure 116 (e.g., the first lower stadium structure 116A). The preliminary steps 139 of the preliminary upper stadium structure 133 may individually horizontally extend substantially continuously in the Y-direction at least across a distance occupied by multiple (e.g., all) lower stadium structures 116 of a column of the lower stadium structures 116 as well as portions of the preliminary stack structure 102 horizontally interposed between horizontally neighboring lower stadium structures 116 of the column.

The preliminary upper stadium structure 133 may include a desired quantity of the preliminary steps 139. As shown in FIG. 3A, in some embodiments, the preliminary steps 139 of the preliminary upper stadium structure 133 are arranged in order, such that preliminary steps 139 directly horizontally adjacent (e.g., in the X-direction) one another correspond to tiers 108 of the preliminary stack structure 102 directly vertically adjacent (e.g., in the Z-direction) one another. In additional embodiments, the preliminary steps 139 of the preliminary upper stadium structure 133 are arranged out of order, such that at least some preliminary steps 139 of the preliminary upper stadium structure 133 directly horizontally adjacent (e.g., in the X-direction) one another correspond to tiers 108 of preliminary stack structure 102 not directly vertically adjacent (e.g., in the Z-direction) one another.

Collectively referring to FIGS. 3A and 3B, a first trench 141 and second trenches 144 may be formed to vertically extend through the upper section 132 of the preliminary stack structure 102. The first trench 141 may be positioned within the second stadium region 114 of the preliminary stack structure 102, and may vertically extend to and expose the preliminary upper stadium structure 133. The preliminary upper stadium structure 133 (including the preliminary forward staircase structure 135A, the preliminary reverse staircase structure 135B, and the preliminary central region 137 thereof) may at least partially define boundaries (e.g., horizontal boundaries, vertical boundaries) of the first trench 141. The first trench 141 exhibits a non-planar lower vertical boundary complementary to (e.g., substantially mirroring) a topography of the preliminary upper stadium structure 133. The second trenches 144 may be positioned within the first stadium region 112 of the preliminary stack structure 102, and may vertically extend to and expose the first filled trenches 123 overlying the lower stadium structures 116. Lower vertical boundaries (e.g., floors) of the second trenches 144 may be substantially horizontally planar, and may be defined by upper boundaries of the dielectric fill materials 124 (including the first dielectric material 126, the second dielectric material 128, and the third dielectric material 130) of the first filled trenches 123. Horizontal boundaries (e.g., sides) of the second trenches 144 may be substantially vertically planar, and may be defined by horizontal boundaries (e.g., sidewalls) of tiers 108 of the upper section 132 of the preliminary stack structure 102.

In some embodiments, the first trench 141 and the second trenches 144 are formed substantially simultaneously (e.g., concurrently) with one another. For example, the first trench 141 (and, hence, the preliminary upper stadium structure 133) may be formed at substantially the same time as each of the second trenches 144. Forming the first trench 141 and the second trenches 144 substantially simultaneously may reduce the processing acts and time required to form the first trench 141 and the second trenches 144. In additional embodiments, the first trench 141 and the second trenches 144 are formed sequentially relative to one another. For example, the first trench 141 (and, hence, the preliminary upper stadium structure 133) may be formed before each of the second trenches 144 are formed. The first trench 141 and the second trenches 144 may be formed within the upper section 132 of the preliminary stack structure 102 using conventional processes (e.g., conventional photolithography processes, conventional masking processes, conventional material removal processes) and conventional processing equipment, which are not described in detail herein.

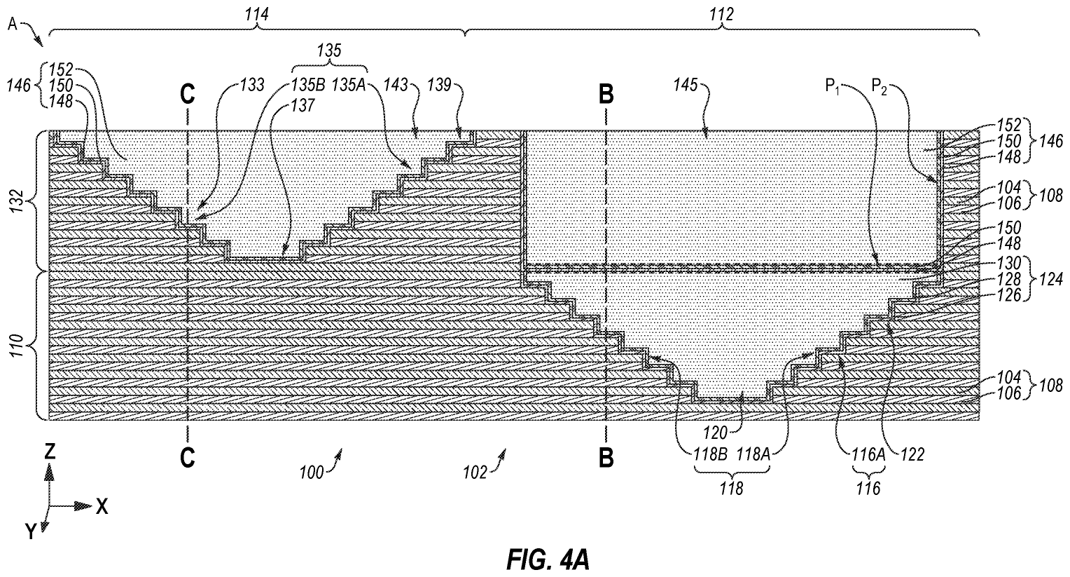

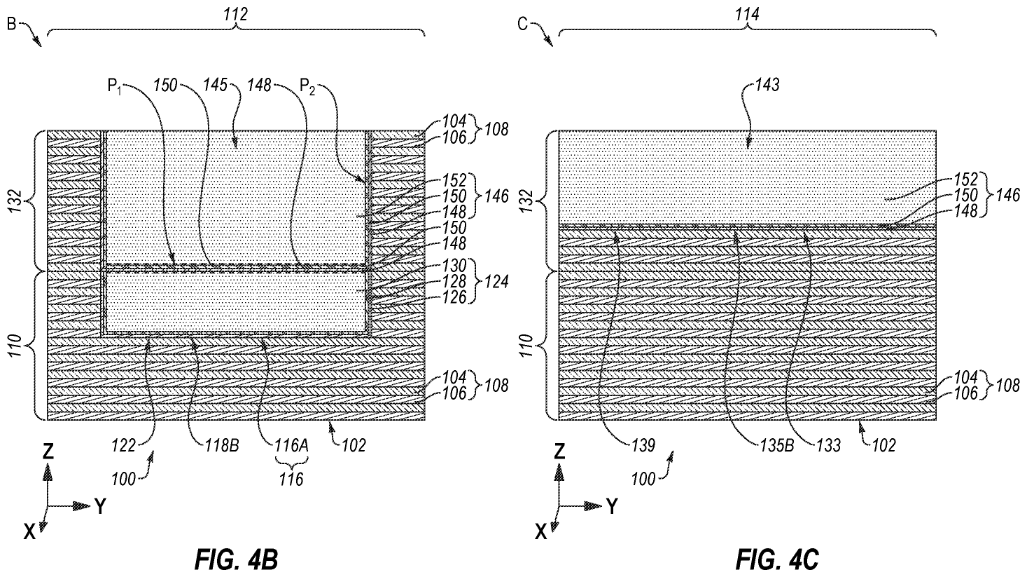

Referring next to FIG. 4A, which is a simplified, longitudinal cross-sectional view of the portion A of the microelectronic device structure 100 following the processing stage previously described with reference to FIGS. 3A through 3D, additional dielectric fill materials 146 may be formed within the first trench 141 (FIGS. 3A and 3B) and the second trenches 144 (FIGS. 3A and 3B) to form a second filled trench 143 and third filled trenches 145, respectively. The additional dielectric fill materials 146 may include a first additional dielectric material 148 (e.g., a first additional dielectric liner material), a second additional dielectric material 150 (e.g., a second additional dielectric liner material), and a third additional dielectric material 152 (e.g., an additional dielectric fill material). The second filled trench 143 may only include the additional dielectric fill materials 146. The third filled trenches 145 may individually include the additional dielectric fill materials 146 and the dielectric fill materials 124 vertically underlying the additional dielectric fill materials 146. As shown in FIG. 4A, uppermost boundaries (e.g., uppermost surfaces) of the second filled trench 143 and individual third filled trenches 145 may be formed to be substantially coplanar with an uppermost boundary (e.g., an uppermost surface) of the upper section 132 of the preliminary stack structure 102. FIG. 4B is a simplified, partial longitudinal cross-sectional view of a portion of the microelectronic device structure 100 at the processing stage of FIG. 4A about the dashed line B-B shown in FIG. 4A. FIG. 4C is a simplified, partial longitudinal cross-sectional view of an additional portion of the microelectronic device structure 100 at the processing stage of FIGS. 4A and 4B about the additional dashed line C-C shown in FIG. 4B.

The first additional dielectric material 148 may be employed (e.g., serve) as a barrier material to mitigate (e.g., limit) exposure of the second additional dielectric material 150 to one or more etchants during subsequent processing acts (e.g., subsequent replacement gate processing acts, such as subsequent etching acts), as described in further detail below. The first additional dielectric material 148 may be formed to have a desired thickness. As shown in FIG. 4A, for the second filled trench 143, the first additional dielectric material 148 may be formed to substantially continuously extend on or over surfaces of the upper section 132 of the preliminary stack structure 102 defining the preliminary upper stadium structure 133. The first additional dielectric material 148 forming a portion of the second filled trench 143 may be formed to be substantially confined within boundaries (e.g., vertical boundaries, horizontal boundaries) of the second filled trench 143. In addition, as also shown in FIG. 4A, for an individual third filled trench 145, the first additional dielectric material 148 may be formed to substantially continuously extend on or over uppermost surfaces of the dielectric fill materials 124 (including uppermost surfaces of the first dielectric material 126, the second dielectric material 128, and the third dielectric material 130), as well as on or over additional surfaces (e.g., sidewalls, side surfaces) of the upper section 132 of the preliminary stack structure 102 defining the second trenches 144 (FIGS. 3A through 3C) As described in further detail below, in additional embodiments, for an individual third filled trench 145, the first additional dielectric material 148 is formed to be substantially absent from an uppermost surface of the third dielectric material 130. The first additional dielectric material 148 forming a portion of an individual third filled trench 145 may be formed to be substantially confined within boundaries (e.g., vertical boundaries, horizontal boundaries) of the individual third filled trench 145.

The first additional dielectric material 148 may be formed of and include at least one dielectric material having different etch selectivity than the sacrificial material 106 of the tiers 108 of the preliminary stack structure 102. The first additional dielectric material 148 may also have different etch selectivity than the second additional dielectric material 150. The first additional dielectric material 148 may, for example, have etch selectively substantially similar to that of the insulative material 104 of the tiers 108 of the preliminary stack structure 102. A material composition of the first additional dielectric material 148 may be substantially the same as a material composition of the first dielectric material 126; or the material composition of the first additional dielectric material 148 may be different than the material composition of the first dielectric material 126. By way of non-limiting example, the first additional dielectric material 148 may be formed of and include at least one oxygen-containing dielectric material, such as a one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric oxynitride material (e.g., SiOₓN_{y}), and at least one dielectric carboxynitride material (e.g., SiOₓC_{z}N_{y}). In some embodiments, the first additional dielectric material 148 is formed of and includes SiOₓ (e.g., SiO₂).

The second additional dielectric material 150 may be employed (e.g., serve) as an etch stop material during subsequent processing acts (e.g., subsequent etching acts) to form openings (e.g., contact openings, contact vias) vertically extending through the third additional dielectric material 152, as described in further detail below. The second additional dielectric material 150 thereof may be formed to have a desired thickness capable of protecting the first additional dielectric material 148 underlying the second additional dielectric material 150 from removal during the subsequent processing acts. As shown in FIG. 4A, for the second filled trench 143, the second additional dielectric material 150 may be formed to substantially continuously extend on or over the first additional dielectric material 148. The second additional dielectric material 150 forming a portion of the second filled trench 143 may be formed to be substantially confined within boundaries (e.g., vertical boundaries, horizontal boundaries) of the second filled trench 143. In addition, as also shown in FIG. 4A, for an individual third filled trench 145, the second additional dielectric material 150 may be formed to substantially continuously extend on or over the first additional dielectric material 148. As described in further detail below, in additional embodiments wherein, for an individual third filled trench 145, the first additional dielectric material 148 is formed to be substantially absent from an uppermost surface of the third dielectric material 130, the first additional dielectric material 148 is also formed to be substantially absent from the uppermost surface of the third dielectric material 130. The second additional dielectric material 150 forming a portion of an individual third filled trench 145 may be formed to be substantially confined within boundaries (e.g., vertical boundaries, horizontal boundaries) of the individual third filled trench 145.

The second additional dielectric material 150 may be formed of and include at least one dielectric material having different etch selectivity than the third additional dielectric material 152. The second additional dielectric material 150 may also have different etch selectivity than the first dielectric material 126. In addition, the second additional dielectric material 150 have different etch selectivity than one or more (e.g., each) of the second dielectric material 128 and the sacrificial material 106 of the tiers 108 of the preliminary stack structure 102. For example, the second additional dielectric material 150 may be more resistant to removal (e.g., may be removed at a relatively slower rate) through exposure to at least one etchant employed during subsequent processing acts (e.g., subsequent replacement gate processing acts, such as subsequent etching acts) to remove the sacrificial material 106 of the tiers 108 than one or more of sacrificial material 106 and the second dielectric material 128. In some embodiments, the second additional dielectric material 150 is configured to be removed relatively slower than at least the sacrificial material 106 of the tiers 108 of the preliminary stack structure 102 during mutual (e.g., common) exposure an etchant utilized to remove the sacrificial material 106. By way of non-limiting example, the second additional dielectric material 150 may be formed of and include one or more of at least one dielectric oxynitride material (e.g., SiOₓN_{y}) and at least one dielectric carboxynitride material (e.g., SiOₓC_{z}N_{y}). In some embodiments, the second additional dielectric material 150 is formed of and includes SiOₓN_{y}.

Still referring to FIG. 4A, the third additional dielectric material 152 may be formed to substantially fill portions of the first trench 141 (FIGS. 3A and 3B) and the second trenches 144 (FIGS. 3A and 3B) remaining unoccupied by the first additional dielectric material 148 and the second additional dielectric material 150. For the second filled trench 143, the third additional dielectric material 152 may be formed to substantially continuously extend on or over the second additional dielectric material 150. The third additional dielectric material 152 forming a portion of the second filled trench 143 may be formed to be substantially confined within boundaries (e.g., vertical boundaries, horizontal boundaries) of the second filled trench 143, may exhibit a substantially planar upper vertical boundary, and may exhibit a substantially non-planar lower vertical boundary complementary to (e.g., substantially mirroring) a topography thereunder. In addition, as shown in FIG. 4A, for an individual third filled trench 145, the third additional dielectric material 152 may be formed to substantially continuously extend on or over the second additional dielectric material 150. As described in further detail below, in additional embodiments wherein, for an individual third filled trench 145, the first additional dielectric material 148 and the second additional dielectric material 150 are formed to be substantially absent from an uppermost surface of the third dielectric material 130, the third additional dielectric material 152 is formed on the uppermost surface of the third dielectric material 130. The third additional dielectric material 152 forming a portion of an individual third filled trench 145 may be formed to be substantially confined within boundaries (e.g., vertical boundaries, horizontal boundaries) of the individual third filled trench 145.

The third additional dielectric material 152 may be formed of and include at least one dielectric material having different etch selectivity than the second additional dielectric material 150. The third additional dielectric material 152 may, for example, have etch selectively substantially similar to that of one or more of the first additional dielectric material 148, the first dielectric material 126, and the insulative material 104 of the tiers 108 of the preliminary stack structure 102. By way of non-limiting example, the third additional dielectric material 152 may be formed of and include at least one oxygen-containing dielectric material, such as a one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric oxynitride material (e.g., SiO_{X}N_{y}), and at least one dielectric carboxynitride material (e.g., SiOₓC_{z}N_{y}). In some embodiments, the third additional dielectric material 152 is formed of and includes SiOₓ (e.g., SiO₂).

As previously discussed, in some embodiments, the first additional dielectric material 148 and the second additional dielectric material 150 are formed to be vertically interposed between the third dielectric material 130 and the third additional dielectric material 152 within the third filled trenches 145. For example, within an individual third filled trench 145, a combination of the first additional dielectric material 148 and the second additional dielectric material 150 may include a first portion P₁ formed to substantially continuously horizontally extend across and substantially cover an upper surface third dielectric material 130; and a second portion P₂ integral and continuous with the first portion P₁ and formed to substantially continuously vertically extend across and substantially cover surfaces (e.g., sidewalls, side surfaces) of the upper section 132 of the preliminary stack structure 102 defining the second trenches 144 (FIGS. 3A through 3C). In some embodiments, the first additional dielectric material 148, the second additional dielectric material 150, and the third additional dielectric material 152 are formed in sequence inside and outside of the second trenches 144 (FIGS. 3A through 3C) and the first trench 141 (FIGS. 3A, 3B, and 3D); and then portions of the first additional dielectric material 148, the second additional dielectric material 150, and the third additional dielectric material 152 outside of the second trenches 144 (FIGS. 3A through 3C) and the first trench 141 (FIGS. 3A, 3B, and 3D) may be removed (e.g., by way of CMP) to form the third filled trenches 145 (individually including the first portion P₁ and the second portion P₂ of the first additional dielectric material 148 and the second additional dielectric material 150; and the third additional dielectric material 152) and the second filled trench 143.

In additional embodiments, within the third filled trenches 145, the third additional dielectric material 152 is formed on (e.g., directly vertically adjacent) the third dielectric material 130. The first additional dielectric material 148 and the second additional dielectric material 150 may still be formed to be horizontally interposed between the third additional dielectric material 152 and the tiers 108 of the insulative material 104 and the sacrificial material 106 of the upper section 132 of the preliminary stack structure 102, but the first additional dielectric material 148 and the second additional dielectric material 150 may not be formed to be vertically interposed between the third additional dielectric material 152 and the third dielectric material 130. For example, within an individual third filled trench 145, the combination of the first additional dielectric material 148 and the second additional dielectric material 150 may formed to include the second portion P₂ substantially continuously vertically extending across and substantially covering surfaces (e.g., sidewalls, side surfaces) of the upper section 132 of the preliminary stack structure 102 defining the second trenches 144 (FIGS. 3A through 3C), but may not include the first portion P₁ substantially continuously horizontally extending across and substantially covering an upper surface third dielectric material 130. Put another way, the first portion P₁ of the first additional dielectric material 148 and the second additional dielectric material 150 may be omitted (e.g., absent) from the third filled trench 145. The potential omission of the first portion P₁ of the first additional dielectric material 148 and the second additional dielectric material 150 is depicted by way of dashed lines in FIGS. 4A and 4B, as well as in subsequent figures. In some embodiments, the first portion P₁ of the first additional dielectric material 148 and the second additional dielectric material 150 is removed from upper surfaces of the third dielectric material 130 prior to be formation of the third additional dielectric material 152. For example, following the formation of the first additional dielectric material 148 and the second additional dielectric material 150 inside and outside of the second trenches 144 (FIGS. 3A through 3C) and the first trench 141 (FIGS. 3A, 3B, and 3D), the first portions P₁ thereof within the second trenches 144 (FIGS. 3A through 3C) may be substantially removed (e.g., etched away) from upper surfaces of the third dielectric material 130 while substantially retaining the second portions P₂ thereof covering the surfaces (e.g., sidewalls, side surfaces) of the upper section 132 of the preliminary stack structure 102 defining the second trenches 144 (FIGS. 3A through 3C). Thereafter, the third additional dielectric material 152 may be formed inside and outside of the second trenches 144 (FIGS. 3A through 3C) and the first trench 141 (FIGS. 3A, 3B, and 3D), and then portions of the first additional dielectric material 148, the second additional dielectric material 150, and the third additional dielectric material 152 outside of the second trenches 144 (FIGS. 3A through 3C) and the first trench 141 (FIGS. 3A, 3B, and 3D) may be removed (e.g., by way of CMP) to form the third filled trenches 145 (individually including the second portion P₂ but not the first portion P₁ of the first additional dielectric material 148 and the second additional dielectric material 150; and the third additional dielectric material 152) and the second filled trench 143.

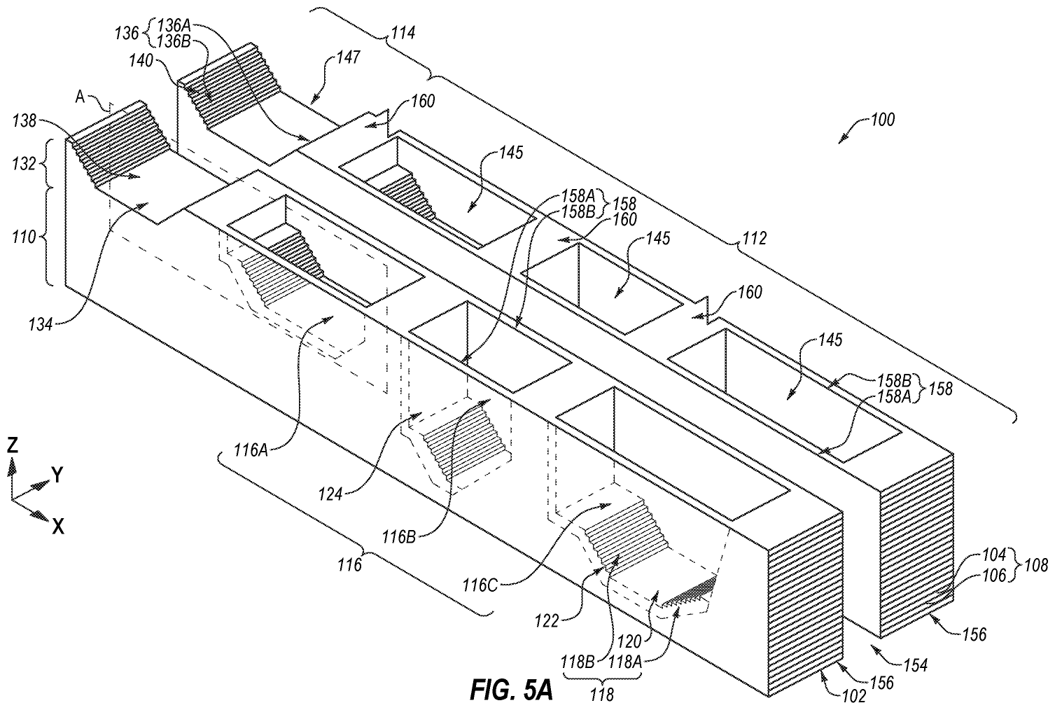

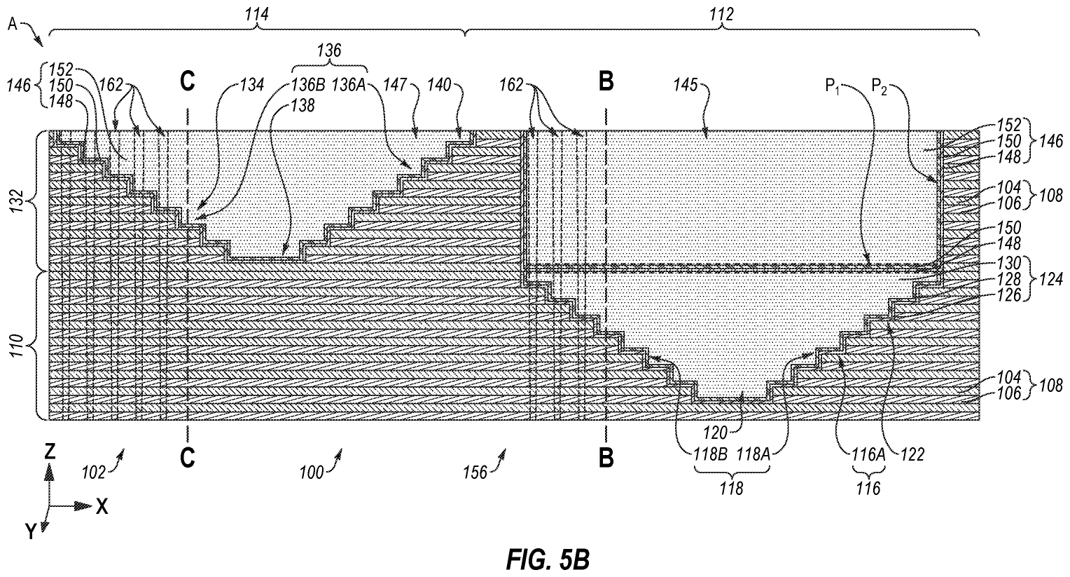

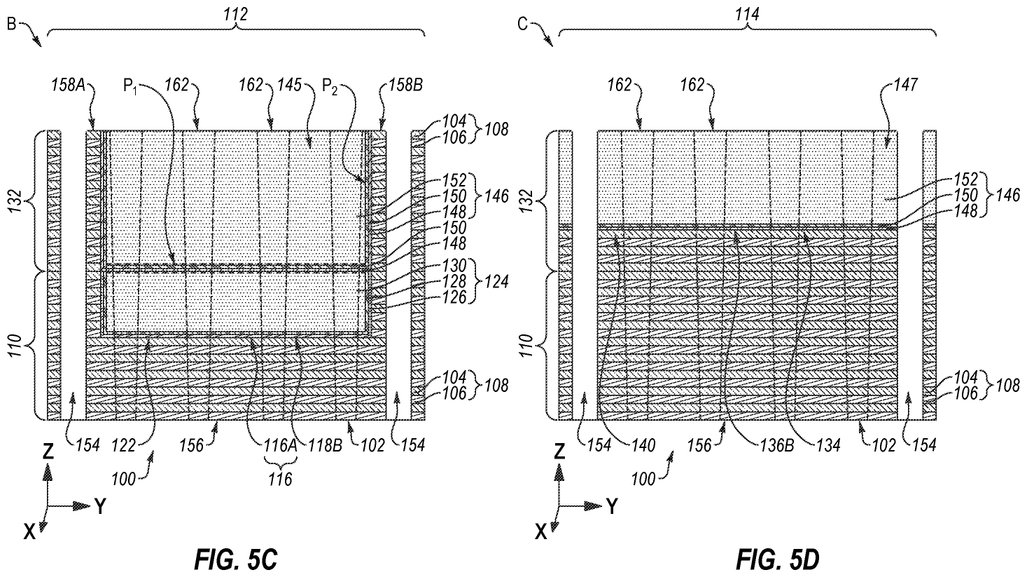

While FIGS. 1A through 4B depict different processing stages (and associated processing acts) to arrive at the configuration of the microelectronic device structure 100 shown in FIGS. 4A through 4C, in accordance with embodiments of methods of the disclosure, other methods employing at least some processing stages (and associated processing acts) different than those described with reference to FIGS. 1A through 4B may be used to arrive at a configuration functionally substantially similar to that of the microelectronic device structure 100 shown in FIGS. 4A through 4C. By way of non-limiting example, in accordance with additional embodiments of the disclosure, an additional method of forming a microelectronic device of the disclosure may include forming an entirety of the preliminary stack structure 102 (including the lower section 110 and the upper section 132 thereof) prior to the formation of any of the lower stadium structures 116 and the preliminary upper stadium structure 133. Thereafter, the preliminary upper stadium structure 133 and a filled trench equivalent to the second filled trench 143 (including the first additional dielectric material 148, the second additional dielectric material 150, and the third additional dielectric material 152) may be formed, before formation of the lower stadium structures 116. Next, the lower stadium structures 116 and associated trenches vertically overlying within horizontal areas of the lower stadium structures 116 may be formed (e.g. through conventional patterning and material removal processes). The associated trenches may vertically extend from uppermost boundaries of the preliminary stack structure 102 to the lower stadium structures 116, similar to the third filled trenches 145 (FIG. 4A) but absent (e.g., free of) the additional dielectric fill materials 146 (FIG. 4A) and the dielectric fill materials 124 (FIG. 4A). Thereafter, the dielectric fill materials 124 (FIG. 3B) (including the first dielectric material 126, the second dielectric material 128, and the third dielectric material 130), may be formed within the trenches associated with the lower stadium structures 116 to form additional filled trenches. The additional filled trenches may be similar to the first filled trenches 123 (FIG. 3B), except that the dielectric fill materials 124 (FIG. 3B) (including the first dielectric material 126, the second dielectric material 128, and the third dielectric material 130) may also vertically extend through the upper section 132 of the preliminary stack structure 102. For example, the first dielectric material 126 may be formed to substantially continuously extend across and substantially cover surfaces of the lower section 110 and the upper section 132 of the preliminary stack structure 102 defining the trenches associated with the lower stadium structures 116; the second dielectric material 128 may be formed to substantially continuously extend across and substantially cover the first dielectric material 126; and the third dielectric material 130 may be formed on or over the second dielectric material 128. The first dielectric material 126, the second dielectric material 128, and the third dielectric material 130 may together to substantially fill the trenches associated with the lower stadium structures 116 to form the additional filled trenches vertically overlying and within horizontal areas of the lower stadium structures 116. Accordingly, unlike the embodiments of the disclosure previously described with reference to FIGS. 4A and 4C, the additional filled trenches may be free of the additional dielectric fill materials 146 (FIG. 4A). The filled trench vertically overlying and within a horizontal area of the preliminary upper stadium structure 133 may include the additional dielectric fill materials 146 (FIG. 4A); and the additional filled trenches vertically overlying and within horizontal areas of the lower stadium structures 116 may include the dielectric fill materials 124 (FIG. 4A), but not the additional dielectric fill materials 146 (FIG. 4A). Following the formation of additional filled trenches, further processing of the resulting microelectronic device structure may proceed in a manner substantially similar to that subsequently described herein with reference to FIGS. 5A through 7C.

Referring next to FIG. 5A, which depicts a simplified, partial perspective view of the microelectronic device structure 100 following the processing stage previously described with reference to FIGS. 4A through 4C, the preliminary stack structure 102 (FIGS. 4A through 3C) may be partitioned (e.g., divided, segmented) to form blocks 156 separated from one another by slots 154 (e.g., slits, openings). The slots 154 may vertically extend (e.g., in the Z-direction) completely through the preliminary stack structure 102. First contact structures 162 (FIGS. 5B through 5D) may also be formed within horizontal areas of the blocks 156, as described in further detail below with reference to FIGS. 5B through 5D. FIG. 5B is a simplified, longitudinal cross-sectional view of the portion A (identified with a dashed box in FIG. 5A) of the microelectronic device structure 100 at the processing stage depicted in FIG. 5A. FIG. 5C is a simplified, partial longitudinal cross-sectional view of a portion of the microelectronic device structure 100 at the processing stage of FIGS. 5A and 5B about the dashed line B-B shown in FIG. 5B. FIG. 5D is a simplified, partial longitudinal cross-sectional view of an additional portion of the microelectronic device structure 100 at the processing stage of FIGS. 5A and 5B about the additional dashed line C-C shown in FIG. 5B.

As shown in FIG. 5A, the blocks 156 of the preliminary stack structure 102 may be formed to horizontally extend parallel in an X-direction. As used herein, the term “parallel” means substantially parallel. Horizontally neighboring blocks 156 of the preliminary stack structure 102 may be separated from one another in a Y-direction orthogonal to the X-direction by the slots 154. The slots 154 may also horizontally extend parallel in the X-direction. Each of the blocks 156 of the preliminary stack structure 102 may exhibit substantially the same geometric configuration (e.g., substantially the same dimensions and substantially the same shape) as each other of the blocks 156, or one or more of the blocks 156 may exhibit a different geometric configuration (e.g., one or more different dimensions and/or a different shape) than one or more other of the blocks 156. In addition, each pair of horizontally neighboring blocks 156 of the preliminary stack structure 102 may be horizontally separated from one another by substantially the same distance (e.g., corresponding to a width in the Y-direction of each of the slots 154) as each other pair of horizontally neighboring blocks 156 of the preliminary stack structure 102, or at least one pair of horizontally neighboring blocks 156 of the preliminary stack structure 102 may be horizontally separated from one another by a different distance than that separating at least one other pair of horizontally neighboring blocks 156 of the preliminary stack structure 102. In some embodiments, the blocks 156 of the preliminary stack structure 102 are substantially uniformly (e.g., substantially non-variably, substantially equally, substantially consistently) sized, shaped, and spaced relative to one another.

Within boundaries of the first stadium region 112 of the preliminary stack structure 102 each block 156 of the preliminary stack structure 102 may individually be formed to include a row of the lower stadium structures 116 (e.g., including the first lower stadium structure 116A, the second lower stadium structure 116B, the third lower stadium structure 116C of the row), crest regions 160 (e.g., elevated regions), and bridge regions 158 (e.g., additional elevated regions). The crest regions 160 may be horizontally interposed between lower stadium structures 116 horizontally neighboring one another in the X-direction. The bridge regions 158 may horizontally neighbor opposing sides of individual lower stadium structures 116 in the Y-direction, and may horizontally extend from and between crest regions 160 horizontally neighboring one another in the X-direction. In FIG. 5A, for clarity and ease of understanding the drawings and associated description, portions (e.g., some of the bridge regions 158 horizontally neighboring first sides of the lower stadium structures 116 in the Y-direction) of one of the blocks 156 of the preliminary stack structure 102 are depicted as transparent to more clearly show the lower stadium structures 116 distributed within the block 156.

As shown in FIG. 5A, the crest regions 160 of an individual block 156 of the preliminary stack structure 102 may intervene between and separate lower stadium structures 116 horizontally neighboring one another in the X-direction. For example, one of the crest regions 160 may intervene between and separate the first lower stadium structure 116A and the second lower stadium structure 1160; and an additional one of the crest regions 160 may intervene between and separate the second lower stadium structure 116B and the third lower stadium structure 116C. A vertical height of the crest regions 160 in the Z-direction may be substantially equal to a maximum vertical height of the block 156 in the Z-direction; and a horizontal width of the crest regions 160 in the Y-direction may be substantially equal to a maximum horizontal width of the block 156 in the Y-direction. In addition, each of the crest regions 160 may individually exhibit a desired horizontal length in the X-direction. Each of the crest regions 160 of an individual block 156 of the preliminary stack structure 102 may exhibit substantially the same horizontal length in the X-direction as each other of the crest regions 160 of the block 156; or at least one of the crest regions 160 of the block 156 may exhibit a different horizontal length in the X-direction than at least one other of the crest regions 160 of the block 156.

Still referring to FIG. 5A, the bridge regions 158 of an individual block 156 of the preliminary stack structure 102 may be formed to intervene between and separate the lower stadium structures 116 of the block 156 from the slots 154 horizontally neighboring the block 156 in the Y-direction. For example, for each lower stadium structure 116 within an individual block 156 of the preliminary stack structure 102, a first bridge region 158A may be horizontally interposed in the Y-direction between a first side of the lower stadium structure 116 and a first of the slots 154 horizontally neighboring the block 156; and a second bridge region 158B may be horizontally interposed in the Y-direction between a second side of the lower stadium structure 116 and a second of the slots 154 horizontally neighboring the block 156. The first bridge region 158A and the second bridge region 158B may horizontally extend in parallel in the X-direction. In addition, the first bridge region 158A and the second bridge region 158B may each horizontally extend from and between crest regions 160 of the block 156 horizontally neighboring one another in the X-direction.

The bridge regions 158 of the block 156 may be integral and continuous with the crest regions 160 of the block 156. Upper boundaries (e.g., upper surfaces) of the bridge regions 158 may be substantially coplanar with upper boundaries of the crest regions 160. A vertical height of the bridge regions 158 in the Z-direction may be substantially equal to a maximum vertical height of the block 156 in the Z-direction. In addition, each of the bridge regions 158 (including each first bridge region 158A and each second bridge region 158B) may individually exhibit a desired horizontal width in the Y-direction and a desired horizontal length in the X-direction. Each of the bridge regions 158 of the block 156 may exhibit substantially the same horizontal length in the X-direction as each other of the bridge regions 158 of the block 156; or at least one of the bridge regions 158 of the block 156 may exhibit a different horizontal length in the X-direction than at least one other of the bridge regions 158 of the block 156. In addition, each of the bridge regions 158 of the block 156 may exhibit substantially the same horizontal width in the Y-direction as each other of the bridge regions 158 of the block 156; or at least one of the bridge regions 158 of the block 156 may exhibit a different horizontal width in the Y-direction than at least one other of the bridge regions 158 of the block 156.

For each block 156 of the preliminary stack structure 102, the bridge regions 158 thereof horizontally extend around the third filled trenches 145 of the block 156. As shown in FIG. 5C, the first dielectric material 126 and the first additional dielectric material 148 of the third filled trenches 145 may be positioned directly horizontally adjacent (e.g., in the Y-direction) inner side surfaces (e.g., inner sidewalls) of the bridge regions 158, and the slots 154 may be positioned directly horizontally adjacent (e.g., in the Y-direction) outer side surfaces (e.g., outer sidewalls) of the bridge regions 158. In some embodiments, portions (e.g., vertically extending portions) of the first dielectric material 126 directly horizontally adjacent the inner side surfaces of the bridge regions 158 at least partially horizontally overlap (e.g., in the Y-direction) portions (e.g., vertically extending portions) of the first additional dielectric material 148 directly horizontally adjacent the inner side surfaces of the bridge regions 158. For example, centerlines of the portions of the first dielectric material 126 may be substantially horizontally aligned with centerlines of the portions of the first additional dielectric material 148 in the Y-direction. In some such embodiments, the bridge regions 158 individually exhibit a substantially uniform (e.g., non-variable, constant) width in the Y-direction across an entire vertical height of the individual bridge region 158 in the Z-direction. In additional embodiments, portions (e.g., vertically extending portions) of the first dielectric material 126 directly horizontally adjacent the inner side surfaces of the bridge regions 158 are horizontally offset (e.g., in the Y-direction) from portions (e.g., vertically extending portions) of the first additional dielectric material 148 directly horizontally adjacent the inner side surfaces of the bridge regions 158. For example, the portions of the first dielectric material 126 may be positioned horizontally inward of the portions of the first additional dielectric material 148 in the Y-direction; or the portions of the first dielectric material 126 may be positioned horizontally outward of the portions of the first additional dielectric material 148 in the Y-direction. In some such embodiments, the bridge regions 158 individually exhibit a variable (e.g., non-uniform, non-constant) width in the Y-direction across a vertical height of the individual bridge region 158 in the Z-direction.

Referring again to FIG. 5A, the formation of the slots 154 may divide the preliminary upper stadium structure 133 (FIG. 4A) into upper stadium structures 134. Each of the blocks 156 may individually include one of the upper stadium structures 134. For an individual block 156, a centerline in the Y-direction of the upper stadium structure 134 thereof may be substantially aligned with centerlines in the Y-direction of the lower stadium structures 116 (e.g., the first lower stadium structure 116A, the second lower stadium structure 116B, the third lower stadium structure 116C) thereof. The centerlines, in the Y-direction, of the upper stadium structure 134 and of the lower stadium structures 116 of an individual block 156 may each be substantially aligned with a centerline, in the Y-direction, of the block 156. As shown in FIG. 5A, the formation of the slots 154 may form a column of the upper stadium structures 134 extending in the Y-direction, wherein each upper stadium structure 134 of the column is positioned within a different block 156 of the preliminary stack structure 102 that each other upper stadium structure 134 of the column Centerlines, in the X-direction, of the upper stadium structures 134 of the column may be substantially aligned with one another.

As shown in FIG. 5A, for an individual block 156, the upper stadium structure 134 thereof may have a greater a horizontal dimension (e.g., horizontal width) in the Y-direction than the lower stadium structures 116 thereof. The upper stadium structure 134 of an individual block 156 may horizontally extend in the Y-direction from and between the slots 154 neighboring opposing sides of the block 156. Conversely, each of the lower stadium structures 116 of the block 156 may horizontally extend in the Y-direction from and between the bridge regions 158 (e.g., the first bridge region 158A, the second bridge region 158B) of the block 156. The bridge regions 158 of an individual block 156 may horizontally intervene between the lower stadium structures 116 of the block 156 and the slots 154 horizontally neighboring the block 156, but the bridge regions 158 of the block 156 may not horizontally intervene between the upper stadium structure 134 of the block 156 and the slots 154 horizontally neighboring the block 156. Horizontal boundaries, in the Y-direction, of the upper stadium structure 134 of an individual block 156 may be substantially aligned with horizontal boundaries, in the Y-direction, of the block 156; and horizontal boundaries, in the Y-direction, of an individual lower stadium structure 116 of the block 156 may be horizontally offset from (e.g., horizontally inward of) horizontal boundaries, in the Y-direction, of the block 156.

Referring collectively to FIGS. 5A and 5B, for an individual block 156, the upper stadium structure 134 thereof may be formed to include opposing staircase structures 136, and a central region 138 horizontally interposed between (e.g., in the X-direction) the opposing staircase structures 136. The opposing staircase structures 136 of the upper stadium structure 134 may include a forward staircase structure 136A and a reverse staircase structure 136B. A phantom line extending from a top of the forward staircase structure 136A to a bottom of the forward staircase structure 136A may have positive slope, and another phantom line extending from a top of the reverse staircase structure 136B to a bottom of the reverse staircase structure 136B may have negative slope. As shown in FIGS. 5A and 5B, forward staircase structure 136A and the reverse staircase structure 136B of the upper stadium structure 134 may be positioned at substantially the same vertical position as one another, and may exhibit topographic profiles substantially mirroring one another.

In additional embodiments, the upper stadium structure 134 of an individual block 156 is formed to exhibit a different configuration than that depicted in FIGS. 5A and 5B. As a non-limiting example, the upper stadium structure 134 may be modified to include a forward staircase structure 136A but not a reverse staircase structure 136B (e.g., the reverse staircase structure 136B may be absent); or the upper stadium structure 134 may be modified to include the reverse staircase structure 136B but not a forward staircase structure 136A (e.g., the forward staircase structure 136A may be absent). In such embodiments, the central region 138 horizontally neighbors a bottom of the forward staircase structure 136A (e.g., if the reverse staircase structure 136B is absent), or the central region 138 horizontally neighbors a bottom of the reverse staircase structure 136B (e.g., if the forward staircase structure 136A is absent). As another non-limiting example, the forward staircase structure 136A may be at least partially (e.g., completely) vertically offset (e.g., in the Z-direction) from the reverse staircase structure 136B. For example, the forward staircase structure 136A may vertically underlie the reverse staircase structure 136B, such that an uppermost boundary of the forward staircase structure 136A is at or below a lowermost boundary of the reverse staircase structure 136B; or the reverse staircase structure 136B may vertically underlie the forward staircase structure 136A, such that an uppermost boundary of the reverse staircase structure 136B is at or below a lowermost boundary of the forward staircase structure 136A. In such embodiments, the central region 138 has a first portion horizontally neighboring a bottom of one of the forward staircase structure 136A and the reverse staircase structure 136B; and a second portion vertically offset from the first portion and horizontally neighboring a bottom of the other of the forward staircase structure 136A and the reverse staircase structure 136B.

For an individual block 156, the opposing staircase structures 136 (e.g., the forward staircase structure 136A and the reverse staircase structure 136B) of the upper stadium structure 134 thereof may be formed to include steps 140 defined by edges (e.g., horizontal ends) of regions of the tiers 108 of the upper section 132 of the preliminary stack structure 102 within the horizontal area of the block 156. Each step 140 of the forward staircase structure 136A may have a counterpart step 140 within the reverse staircase structure 136B having substantially the same geometric configuration (e.g., shape, dimensions), vertical position (e.g., in the Z-direction), and horizontal distance (e.g., in the X-direction) from a horizontal center (e.g., in the X-direction) of the central region 138 of the upper stadium structure 134. In additional embodiments, at least one step 140 of the forward staircase structure 136A does not have a counterpart step 140 within the reverse staircase structure 136B having substantially the same geometric configuration (e.g., shape, dimensions), vertical position (e.g., in the Z-direction), and/or horizontal distance (e.g., in the X-direction) from the horizontal center (e.g., in the X-direction) of the central region 138 of the upper stadium structure 134; and/or at least one step 140 of the reverse staircase structure 136B does not have a counterpart step 140 within the forward staircase structure 136A having substantially the same geometric configuration (e.g., shape, dimensions), vertical position (e.g., in the Z-direction), and/or horizontal distance (e.g., in the X-direction) from horizontal center (e.g., in the X-direction) of the central region 138 of the upper stadium structure 134.

As shown in FIG. 5A, for an individual block 156, a horizontal dimension (e.g., horizontal width) in the Y-direction of the steps 140 of the upper stadium structure 134 thereof may be greater than the horizontal dimension in the Y-direction of the steps 122 of an individual lower stadium structure 116 (e.g., the first lower stadium structure 116A) thereof. The steps 140 of the upper stadium structure 134 individually horizontally extend from and between the slots 154 neighboring opposing sides of the block 156. In contrast, the steps 122 of an individual lower stadium structure 116 (e.g., the first lower stadium structure 116A) of the block 156 horizontally extend from and between the bridge regions 158 (e.g., the first bridge region 158A, the second bridge region 158B) of the block 156. Horizontal boundaries, in the Y-direction, of the steps 140 of the upper stadium structure 134 may be substantially aligned with horizontal boundaries, in the Y-direction, of the block 156; and horizontal boundaries, in the Y-direction, of the steps 122 of an individual lower stadium structure 116 of the block 156 may be horizontally offset from (e.g., horizontally inward of) horizontal boundaries, in the Y-direction, of the block 156.

Still referring to FIG. 5A, the formation of the slots 154 may divide the second filled trench 143 (FIG. 4A) into fourth filled trenches 147. Each of the blocks 156 may individually include one of the fourth filled trenches 147 vertically overlying and within a horizontal area of the upper stadium structure 134 thereof. Each of the fourth filled trenches 147 may include the additional dielectric fill materials 146, including the first additional dielectric material 148, the second additional dielectric material 150, and the third additional dielectric material 152. As shown in FIG. 5D, for an individual block 156, the additional dielectric fill materials 146 of the fourth filled trench 147 horizontally extend from and between the slots 154 neighboring opposing sides of the block 156. Sides (e.g., sidewalls) of each of the first additional dielectric material 148, the second additional dielectric material 150, and the third additional dielectric material 152 of the additional dielectric fill materials 146 of the fourth filled trench 147 may be exposed by the slots 154 neighboring the opposing sides of the block 156. In contrast, as shown in FIG. 5C, for an individual block 156, the additional dielectric fill materials 146 of one of the third filled trenches 145 horizontally extend from and between the bridge regions 158 (e.g., the first bridge region 158A, the second bridge region 158B) of the block 156. Sides (e.g., sidewalls) of each of the first additional dielectric material 148, the second additional dielectric material 150, and the third additional dielectric material 152 of the additional dielectric fill materials 146 of the third filled trench 145 may not be exposed by the slots 154 neighboring the opposing sides of the block 156. Rather, the bridge regions 158 of the block 156 may be horizontally interposed between the slots 154 neighboring the opposing sides of the block 156 and the additional dielectric fill materials 146 of the third filled trench 145.

Referring collectively to FIGS. 5B through 5D, the first contact structures 162 may be formed to vertically extend (e.g., in the Z-direction) through the blocks 156 of the preliminary stack structure 102. The first contact structures 162 may individually be formed to vertically extend from an upper boundary of the preliminary stack structure 102, through the preliminary stack structure 102, and to or beyond a lower boundary of the preliminary stack structure 102. At least some of the first contact structures 162 may be configured and positioned to facilitate support of the insulative material 104 of each of the tiers 108 of the preliminary stack structure 102 during subsequent removal of the sacrificial material 106 of the tiers 108, as described in further detail below. In each of FIGS. 5B through 5D, horizontal offset of the first contact structures 162 from the longitudinal cross-sectional plane being illustrated is depicted by way of dashed lines at the boundaries (e.g., horizontal boundaries, vertical boundaries) of the first contact structures 162. The first contact structures 162 are omitted from FIG. 5A for clarity and ease of understanding the drawings and associated description. In addition, in FIG. 5B, for clarity and ease of understanding the drawings and associated description, only some of the first contact structures 162 that may otherwise be formed within the portion A of the microelectronic device structure 100 are depicted. However, it will be understood that any desirable quantity and distribution of the first contact structures 162 may be formed within the microelectronic device structure 100, including within the portion A thereof depicted in FIG. 5B.

In some embodiments, each block 156 of the preliminary stack structure 102 includes at least one array of the first contact structures 162 vertically extending therethrough, including rows of the first contact structures 162 extending in the X-direction, and columns of the first contact structures 162 extending to the Y-direction. As a non-limiting example, for an individual block 156, an array of the first contact structures 162 formed therein may include at least two (2) rows (e.g., at least four (4) rows) of the first contact structures 162 each extending in the X-direction. In some embodiments, each block 156 of the preliminary stack structure 102 individually includes at least one array of the first contact structures 162 exhibiting at least four (4) rows of the first contact structures 162.

For an individual block 156 of the preliminary stack structure 102, a group of the first contact structures 162 may be formed within a horizontal area of the upper stadium structure 134 of the block 156, and an additional group of the first contact structures 162 may formed within horizontal areas of the lower stadium structures 116 of the block 156. The group of the first contact structures 162 may vertically extend through the fourth filled trench 147, and through portions of the tiers 108 of the preliminary stack structure 102 vertically underlying and within a horizontal area of the fourth filled trench 147. The additional group of the first contact structures 162 may vertically extend through the third filled trenches 145, and through additional portions of the tiers 108 of the preliminary stack structure 102 vertically underlying and within horizontal areas of the third filled trenches 145.

The first contact structures 162 may each individually be formed to exhibit a desired horizontal cross-sectional shape. In some embodiments, each of the first contact structures 162 is formed to exhibit a substantially circular horizontal cross-sectional shape. In additional embodiments, one or more (e.g., each) of the first contact structures 162 exhibits a non-circular cross-sectional shape, such as one of more of a square cross-sectional shape, a rectangular cross-sectional shape, an oblong cross-sectional shape, an elliptical cross-sectional shape, a tear drop cross-sectional shape, a semicircular cross-sectional shape, a tombstone cross-sectional shape, a crescent cross-sectional shape, a triangular cross-sectional shape, a kite cross-sectional shape, and an irregular cross-sectional shape. In addition, each of the first contact structures 162 may be formed to exhibit substantially the same horizontal cross-sectional dimensions (e.g., substantially the same horizontal diameter), or at least one of the first contact structures 162 may be formed to exhibit one or more different horizontal cross-sectional dimensions (e.g., a different horizontal diameter) than at least one other of the first contact structures 162. In some embodiments, all of the first contact structures 162 are formed to exhibit substantially the same horizontal cross-sectional dimensions.

The first contact structures 162 may each individually be formed of and include at least one conductive material, such as one or more of at least one metal (e.g., W, Ti, Mo, Nb, V, Hf, Ta, Cr, Zr, Fe, Ru, Os, Co, Rh, Ir, Ni, Pa, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, a stainless steel), at least one conductive metal-containing material (e.g., a conductive metal nitride, a conductive metal silicide, a conductive metal carbide, a conductive metal oxide), and at least one conductively-doped semiconductor material (e.g., conductively-doped Si, conductively-doped Ge, conductively-doped SiGe). In addition, at least one insulative liner material may be formed to substantially surround (e.g., substantially horizontally and vertically cover) side surfaces (e.g., sidewalls) of each of the first contact structures 162. The insulative liner material may be horizontally interposed between the first contact structures 162 and the insulative material 104 and the sacrificial material 106 of tiers 108 of the preliminary stack structure 102. The insulative liner material may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the insulative liner material comprises SiO₂.

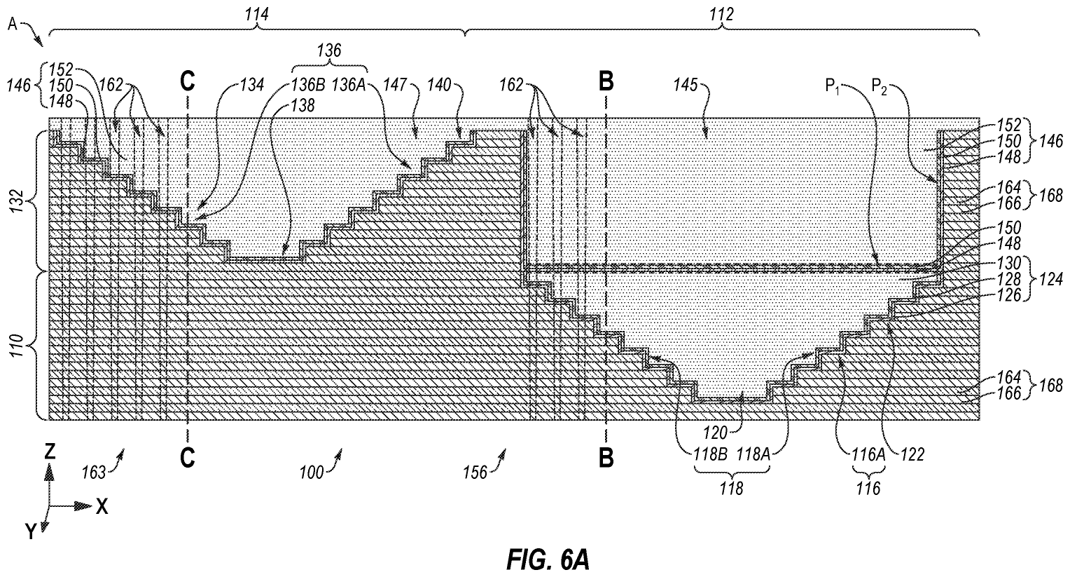

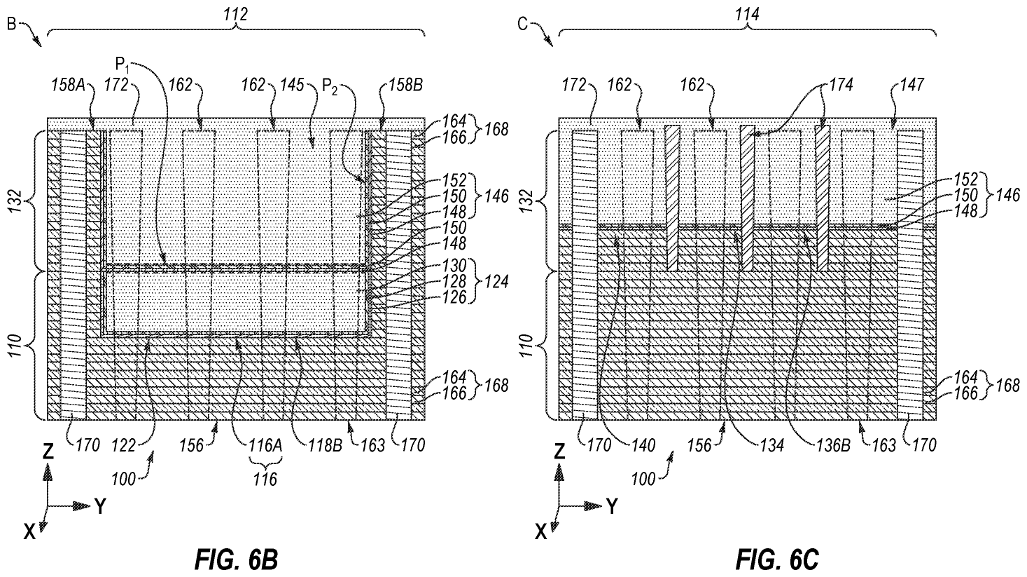

Referring next to FIG. 6A, which is a simplified, longitudinal cross-sectional view of the portion A of the microelectronic device structure 100 following the processing stage previously described with reference to FIGS. 5A through 5D, the preliminary stack structure 102 (FIGS. 5A through 5D) may subject to replacement gate processing to form a stack structure 163, and then the slots 154 (FIGS. 5A, 5C, and 5D) may be filled with dielectric material to form dielectric slot structures 170. FIG. 6B is a simplified, partial longitudinal cross-sectional view of a portion of the microelectronic device structure 100 at the processing stage of FIG. 6A about the dashed line B-B shown in FIG. 6A. FIG. 6C is a simplified, partial longitudinal cross-sectional view of an additional portion of the microelectronic device structure 100 at the processing stage of FIGS. 6A and 6B about the additional dashed line C-C shown in FIG. 6A. Additional features (e.g., additional materials, additional structures) of the microelectronic device structure 100 at the processing stage of FIGS. 6A through 6C are described in further detail below.

Referring collectively to FIGS. 6A through 6C, the stack structure 163 may be divided into the blocks 156 previously described with reference to FIGS. 5A through 5D. Each of the blocks 156 of the stack structure 163 may be formed to include a vertically alternating (e.g., in a Z-direction) sequence of insulative structures 164 and conductive structures 166 arranged in tiers 168. For an individual block 156 of the stack structure 163, each of the tiers 168 may individually include one of the conductive structures 166 vertically neighboring (e.g., directly vertically adjacent) one of the insulative structures 164. The insulative structures 164 of the blocks 156 of the stack structure 163 may comprise portions of the insulative material 104 (FIGS. 5A through 5D) of the preliminary stack structure 102 (FIGS. 5A through 5D) remaining following the formation of the conductive structures 166. The conductive structures 166 of the blocks 156 of the stack structure 163 may comprise at least one conductive material formed (e.g., deposited) in place of the sacrificial material 106 (FIGS. 5A through 5D) of the tiers 108 (FIGS. 5A through 5D) of the preliminary stack structure 102 (FIGS. 5A through 5D) through the replacement gate process, as described in further detail below. In some embodiments, the conductive structures 166 are formed of and include W. Optionally, at least one liner material (e.g., at least one insulative liner material, at least one conductive liner materials) may be formed around the conductive structures 166. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive structures 166. In additional embodiments, the liner material comprises titanium nitride (TiNₓ, such as TiN). In further embodiments, the liner material further includes aluminum oxide (AlOₓ, such as Al₂O₃). As a non-limiting example, for each of the block 156 of the stack structure 163, AlOₓ (e.g., Al₂O₃) may be formed directly adjacent the insulative structures 164, TiNₓ (e.g., TiN) may be formed directly adjacent the AlOₓ, and W may be formed directly adjacent the TiNₓ. For clarity and ease of understanding the description, the liner material is not illustrated in FIGS. 6A through 6C, but it will be understood that the liner material may be disposed around the conductive structures 166.

To form the stack structure 163 through replacement gate processing, the microelectronic device structure 100 may be treated with at least one wet etchant formulated to selectively remove portions of the sacrificial material 106 (FIGS. 5A through 5D) of the tiers 108 (FIGS. 5A through 5D) of the preliminary stack structure 102 (FIGS. 5A through 5D) through the slots 154 (FIGS. 5A, 5C, and 5D). The wet etchant may be selected to remove the portions of the sacrificial material 106 (FIGS. 5A through 5D) without substantially removing portions of the insulative material 104 (FIGS. 5A through 5D) of the tiers 108 (FIGS. 5A through 5D) of the preliminary stack structure 102 (FIGS. 5A through 5D). In some embodiments wherein the sacrificial material 106 (FIGS. 5A through 5D) comprises dielectric nitride material (e.g., SiN_{y}, such as Si₃N₄) and the insulative material 104 (FIGS. 5A through 5D) comprise dielectric oxide material (e.g., SiOₓ, such as SiO₂), the sacrificial material 106 (FIGS. 5A through 5D) of the tiers 108 (FIGS. 5A through 5D) of the preliminary stack structure 1202 (FIGS. 5A through 5D) is selectively removed using a wet etchant comprising H₃PO₄. Following the selective removal of the portions of the sacrificial material 106 (FIGS. 5A through 5D), the resulting recesses may be filled with conductive material to form the conductive structures 166 of the blocks 156 of the stack structure 163.

Collectively referring to FIGS. 5B through 5D, during the removal of the sacrificial material 106 of the tiers 108 of the preliminary stack structure 102 using wet etchant, the materials (e.g., the dielectric fill materials 124, the additional dielectric fill materials 146) of the third filled trenches 145 and the fourth filled trenches 147 may be substantially maintained. Referring to FIG. 5C, within the third filled trenches 145, the first dielectric material 126 and the first additional dielectric material 148 may respectively protect (e.g., mask) the second dielectric material 128 and the second additional dielectric material 150 from exposure to wet etchant being directed into the slots 154 to remove the sacrificial material 106 of the tiers 108. In addition, referring to FIG. 5D, within the fourth filled trenches 147, the etch resistance properties of the second additional dielectric material 150 may substantially limit (e.g., substantially prevent) portions of the second additional dielectric material 150 exposed by the slots 154 from being removed by the wet etchant being directed into the slots 154 to remove the sacrificial material 106 of the tiers 108.

Referring collectively to FIGS. 6B and 6C, following the formation of stack structure 163, the slots 154 (FIGS. 5A, 5C, and 5D) between the blocks 156 may be filled (e.g., substantially filled) with at least one dielectric material (e.g., at least one dielectric oxide material, such as SiOₓ; at least one dielectric nitride material, such as SiN_{y}) to form the dielectric slot structures 170. In some embodiments, the dielectric slot structures 170 are formed of and include SiOₓ (e.g., SiO₂). The dielectric slot structures 170 may individually be formed to be substantially homogeneous, or may individually be formed to be heterogeneous. In addition, at least one further dielectric material 172 may be formed over the blocks 156 and the dielectric slot structures 170. An uppermost boundary of the further dielectric material 172 may vertically overlie (e.g., in the Z-direction) uppermost boundaries (e.g., an uppermost surface) of an uppermost tier 168 of the stack structure 163. A material composition of the further dielectric material 172 may be substantially the same as a material composition of the dielectric slot structures 170, or the material composition of the further dielectric material 172 may be different than the material composition of the dielectric slot structures 170. In some embodiments, the further dielectric material 172 is formed of and includes SiOₓ (e.g., SiO₂).

Referring to FIG. 6C, for an individual block 156 of the stack structure 163, the conductive structures 166 of at least some of the tiers 168 within the upper section 132 of the stack structure 163 may be employed as upper select gate structures (e.g., drain side select gate (SGD) structures) for upper select transistors (e.g., drain side select transistors) formed within an array region of the block 156 horizontally neighboring the second stadium region 114 including the upper stadium structure 134 (FIG. 6A). The conductive structures 166 of at least some of the tiers 168 within the upper section 132 may be segmented by one or more additional dielectric slot structures 174 (e.g., filled SGD slot(s)) to form the upper select gate structures of the block 156. As a non-limiting example, the additional dielectric slot structures 174 may individually horizontally extend into less than or equal to eight (8) relatively higher tiers 168 (e.g., from one (1) relatively vertically higher tier 168 to eight (8) relatively vertically higher tiers 168) of the stack structure 163. Accordingly, for an individual block 156 of the stack structure 163, less than or equal to eight (8) relatively higher tiers 168 may be employed as upper select gate structures (e.g., SGD structures) of the block 156. In addition, for an individual block 156, the additional dielectric slot structures 174 may horizontally extend (e.g., in the X-direction) through the array region and at least partially into the second stadium region 114. For an individual block 156, the additional dielectric slot structures 174 may horizontally extend at least into a horizontal area of one of the opposing staircase structures 136 (e.g., the reverse staircase structure 136B) of the upper stadium structure 134 of the block 156. In some embodiments, for an individual block 156, each of the additional dielectric slot structures 174 horizontally terminates (e.g., horizontally ends) in the X-direction at or proximate a relatively lowest step 140 of the one of the opposing staircase structures 136 (e.g., the reverse staircase structure 136B) of the upper stadium structure 134 of the block 156.

Each of the additional dielectric slot structures 174 may comprise a slot (e.g., opening, trench, slit) in a block 156 of the stack structure 163 filled with at least one dielectric material. A material composition of the additional dielectric slot structures 174 may be substantially the same as a material composition of the dielectric slot structures 170, or the material composition of the additional dielectric slot structures 174 may be different than the material composition of the dielectric slot structures 170. In some embodiments, the additional dielectric slot structures 174 are formed of and include at least one dielectric oxide material (e.g., SiOₓ, such as SiO₂).

Each block 156 of the stack structure 163 may include greater than or equal to one (1) of the additional dielectric slot structures 174 within a horizontal area thereof, such as greater than or equal to two (2) of the additional dielectric slot structures 174, or greater than or equal to three (3) of the additional dielectric slot structures 174. In some embodiments, each block 156 of the stack structure 163 includes three (3) of the additional dielectric slot structures 174 within a horizontal area thereof. The additional dielectric slot structures 174 may sub-divide each block 156 into at least two (2) sub-blocks. For example, as shown in FIG. 6C, if an individual block 156 includes three (3) of the additional dielectric slot structures 174 within a horizontal area thereof, the additional dielectric slot structures 174 may sub-divide the block 156 into four (4) sub-blocks. For an individual block 156, portions of the conductive structures 166 of individual tiers 168 within the upper section 132 of the stack structure 163 and within horizontal areas of the sub-blocks of the block 156 may form the upper select gate structures (e.g., SGD structures) of the block 156.

Again referring collectively to FIGS. 6A through 6C, for an individual block 156 of the stack structure 163, the conductive structures 166 of at least some of the tiers 168 within the lower section 110 of the stack structure 163 may be employed as access line structures (e.g., word line structures) of the block 156. Moreover, for an individual block 156 of the stack structure 163, the conductive structures 166 of at least a vertically lowest tier 168 within the lower section 110 of the stack structure 163 may be employed as at least one lower select gate structure (e.g., at least one source side select gate (SGS) structure) for lower select transistors (e.g., source side select transistors) within the array region of the block 156.

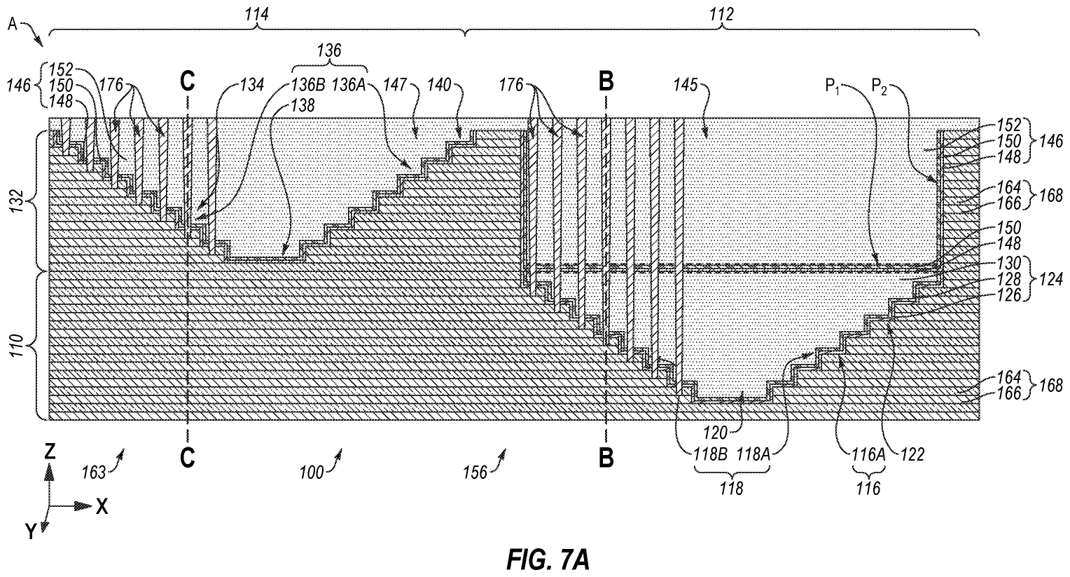

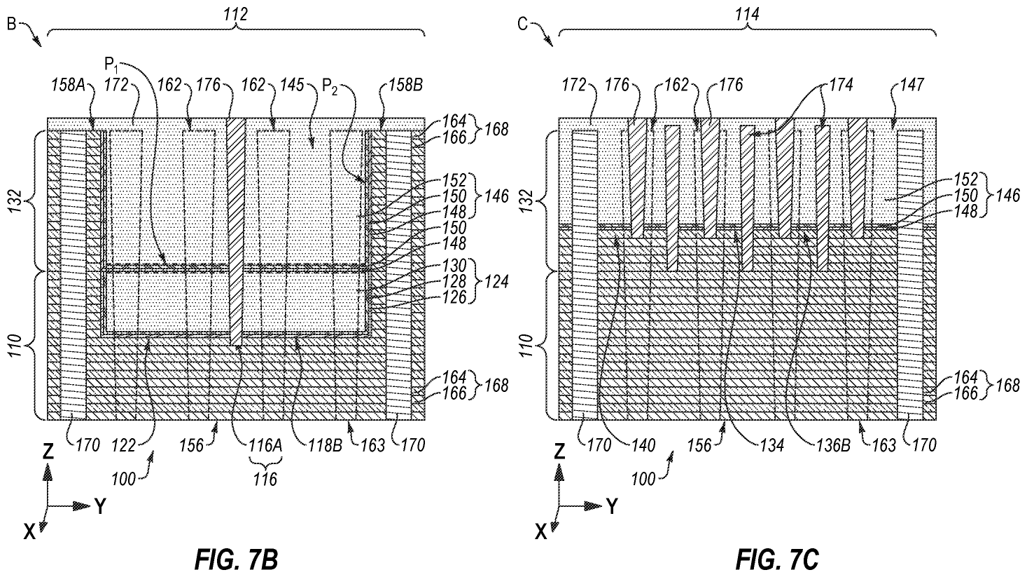

Referring next to FIG. 7A, which is a simplified, longitudinal cross-sectional view of the portion A of the microelectronic device structure 100 following the processing stage previously described with reference to FIGS. 6A through 6C, for an individual block 156 of the stack structure 163, second contact structures 176 may be formed to vertical extend to and contact the conductive structures 166 of at least some of the tiers 168 of the stack structure 163. For an individual block 156, some of the second contact structures 176 may be formed to vertically extend through the third filled trenches 145 and contact (e.g., physically contact, electrically contact) at least some of the conductive structures 166 within vertical boundaries of the lower section 110 of the stack structure 163 at at least some of the steps 122 of individual lower stadium structures 116. In addition, for an individual block 156, some other of the second contact structures 176 may be formed to vertically extend through the fourth filled trench 147 and contact (e.g., physically contact, electrically contact) at least some of the conductive structures 166 within vertical boundaries of the upper section 132 of the stack structure 163 at at least some of the steps 140 of the upper stadium structure 134. In FIG. 7A, the first contact structures 162 (FIGS. 6A through 6C) are omitted for clarity and ease of understanding the drawings and associated description in relation to the second contact structures 176. FIG. 7B is a simplified, partial longitudinal cross-sectional view of a portion of the microelectronic device structure 100 at the processing stage of FIG. 7A about the dashed line B-B shown in FIG. 7A. FIG. 7C is a simplified, partial longitudinal cross-sectional view of an additional portion of the microelectronic device structure 100 at the processing stage of FIGS. 7A and 7B about the additional dashed line C-C shown in FIG. 7A.

Referring collectively to FIGS. 7A and 7B, desirable arrangements of the second contact structures 176 may be formed within horizontal areas of the lower stadium structures 116 of an individual block 156 of the stack structure 163. In some embodiments, at least one (1) row of the second contact structures 176 is formed with a horizontal area of each of the lower stadium structures 116. Each row of the second contact structures 176 may horizontally extend in the X-direction, and may individually include a portion of the second contact structures 176 provided within a horizontal area of the block 156. The second contact structures 176 of each row may land on at least some of the steps 122 of the lower stadium structures 116. In some embodiments, each of the lower stadium structures 116 includes a single (e.g., only one (1)) row of the second contact structures 176 within a horizontal area thereof. A horizontal centerline of the single row of the second contact structures 176 may be substantially aligned with a horizontal centerline of the block 156, or the horizontal centerline of the single row of the second contact structures 176 may be horizontally offset (e.g., in the Y-direction) from the horizontal centerline of the block 156. In additional embodiments, at least one of the lower stadium structures 116 includes more than one (1) row of the second contact structures 176 within a horizontal area thereof, such as at least two (2) rows of the second contact structures 176, at least three (3) rows of the second contact structures 176, or at least four (3) rows of the second contact structures 176. In further embodiments, the second contact structures 176 are provided on steps 122 of at least one (e.g., each) of the lower stadium structures 116 in a different arrangement than in one or more of rows horizontally extending in the X-direction. For example, the second contact structures 176 may be arranged in a diagonal pattern extending substantially linearly in the X-direction and the Y-direction on steps 122 of the at least one of the lower stadium structures 116, or may be arranged in an at least partially non-linear pattern (e.g., a curved pattern, a zigzag pattern, a random pattern, an irregular pattern) on steps 122 of at least one of the lower stadium structures 116. In some embodiments, within horizontal areas of the lower stadium structures 116 of an individual block 156, at least some (e.g., each) of the second contact structures 176 are horizontally offset, in each of the X-direction and the Y-direction, from the first contact structures 162 most proximate thereto.

Referring collectively to FIGS. 7A and 7C, desirable arrangements of the second contact structures 176 may also be formed within a horizontal area of the upper stadium structure 134 of an individual block 156 of the stack structure 163. In some embodiments, within a horizontal area of the upper stadium structure 134 of an individual block 156 each sub-block of the block 156 includes a row of the second contact structures 176. For example, if an individual block 156 is formed to include four (4) sub-blocks (e.g., by way of three (3) of the additional dielectric slot structures 174), within horizontal boundaries of the upper stadium structure 134 each of the four (4) sub-blocks may include one (1) row of the second contact structures 176 within a horizontal area thereof. Each such row of the second contact structures 176 may horizontally extend in the X-direction, and may include a portion of the second contact structures 176 provided within a horizontal area of the upper stadium structure 134. In addition, as depicted in FIG. 7C, within an individual block 156 of the stack structure 163, columns of the second contact structures 176 may horizontally extend in the Y-direction. Each column of the second contact structures 176 may include second contact structures 176 provided within different sub-blocks of the block 156 than one another. In some embodiments, within a horizontal area of the upper stadium structure 134 of an individual block 156, at least some (e.g., each) of the second contact structures 176 are horizontally aligned in the Y-direction with the first contact structures 162 most proximate thereto.

The second contact structures 176 may each individually be formed to exhibit a desired horizontal cross-sectional shape. In some embodiments, each of the second contact structures 176 is formed to exhibit a substantially circular horizontal cross-sectional shape. In additional embodiments, one or more (e.g., each) of the second contact structures 176 exhibits a non-circular cross-sectional shape, such as one more of an oblong cross-sectional shape, an elliptical cross-sectional shape, a square cross-sectional shape, a rectangular cross-sectional shape, a tear drop cross-sectional shape, a semicircular cross-sectional shape, a tombstone cross-sectional shape, a crescent cross-sectional shape, a triangular cross-sectional shape, a kite cross-sectional shape, and an irregular cross-sectional shape. In addition, each of the second contact structures 176 may be formed to exhibit substantially the same horizontal cross-sectional dimensions (e.g., substantially the same horizontal diameter), or at least one of the second contact structures 176 may be formed to exhibit one or more different horizontal cross-sectional dimensions (e.g., a different horizontal diameter) than at least one other of the second contact structures 176. In some embodiments, all of the second contact structures 176 are formed to exhibit substantially the same horizontal cross-sectional dimensions.

The second contact structures 176 may be formed of and include conductive material. As a non-limiting example, the second contact structures 176 may be formed of and include one or more of at least one metal, at least one alloy, and at least one conductive metal-containing material (e.g., a conductive metal nitride, a conductive metal silicide, a conductive metal carbide, a conductive metal oxide). A material composition of the second contact structures 176 may be substantially the same as a material composition of the conductive structures 166 of the tiers 168 of the stack structure 163, or the material composition of the second contact structures 176 may be different than the material composition of the conductive structures 166 of the tiers 168 of the stack structure 163. In some embodiments, the second contact structures 176 are individually formed of and include W. The second contact structures 176 may individually be homogeneous, or the second contact structures 176 may individually be heterogeneous.

The second contact structures 176 may be formed using multiple material removal acts, and at least one material deposition act. For example, for an individual block 156, initial contact openings may be formed within third filled trenches 145 and the fourth filled trenches 147 through at least one initial material removal act (e.g., an initial etching act) to expose portions of the second dielectric material 128 overlying the steps 122 of the lower stadium structures 116 and to expose portions of the second additional dielectric material 150 overlying the steps 140 of the upper stadium structures 134, respectively. During the initial material removal act, the second dielectric material 128 and the second additional dielectric material 150 may serve as a so-called “etch stop” materials to protect underlying portions of the first dielectric material 126 and the first additional dielectric material 148 from removal, respectively. Thereafter, at least one additional material removal act (e.g., an additional etching act) may be performed to vertically extend the initial contact openings to the conductive structures 166 of at least some of the tiers 168 of the stack structure 163. Within horizontal areas of the lower stadium structures 116, portions of at least the second dielectric material 128 and the first dielectric material 126 (and, depending on a vertical arrangement of the insulative structures 164 and the conductive structures 166, portions of the insulative structures 164) within horizontal boundaries of some of the initial contact openings may be removed to vertically extend the some of the initial contact openings to the conductive structures 166 at steps 122 of the lower stadium structures 116. Within a horizontal area of the upper stadium structure 134, portions of at least the second additional dielectric material 150 and the first additional dielectric material 148 (and, depending on a vertical arrangement of the insulative structures 164 and the conductive structures 166, portions of the insulative structures 164) within horizontal boundaries of some other of the initial contact openings may be removed to vertically extend the some other of the initial contact openings to the conductive structures 166 at steps 140 of the upper stadium structure 134. Following the formation of the extended contact openings, conductive material may be formed inside and outside of the extended contact openings using at least one material deposition process (e.g., a non-conformal material deposition process), and then portions of the conductive material outside of boundaries (e.g., vertical boundaries, horizontal boundaries) of the extended contact openings may be removed (e.g., through an abrasive planarization process, such as a CMP process) to form the second contact structures 176.

During the process of forming some of the second contact structures 176 to contact steps 140 of the upper stadium structure 134 of an individual block 156, the relatively wider dimensions of the upper stadium structure 134 in the Y-direction as compared to the lower stadium structures 116 mitigates the likelihood of undesirable positioning of the second contact structures 176 relative to the steps 140 of the upper stadium structure 134. For example, as the upper stadium structure 134 horizontally extends in the Y-direction from and between the dielectric slot structures 170, there is greater margin for proper placement of the second contact structures 176 on the steps 140 of the upper stadium structure 134—particularly for those second contact structures 176 to be provided within horizontal areas of the sub-blocks (as defined and divided by the additional dielectric slot structures 174) horizontally neighboring the dielectric slot structures 170—than there would otherwise be for an upper stadium structure bounded by the bridge regions 158 (e.g., in the same manner as the lower stadium structures 116) of the block 156. Not having the upper stadium structure 134 horizontally extend from and between bridge regions 158 of the block 156 circumvents the risk of having the second contact structures 176 formed most proximate the dielectric slot structures 170 undesirably physically contact and/or damage (e.g., clip) such bridge regions 158 and/or materials (e.g., liner materials) formed thereon.

Thus, in accordance with embodiments of the disclosure, a microelectronic device comprises a stack structure comprising blocks separated from one another by dielectric slot structures and each including a vertically alternating sequence of conductive structures and insulative structures arranged in tiers. At least one of the blocks comprises an upper stadium structure, two crest regions, a lower stadium structure, and two bridge regions. The upper stadium structure extends in a first horizontal direction from and between two of the dielectric slot structures. The upper stadium structure comprises staircase structures having steps comprising edges of some of the tiers. The two crest regions are offset from the upper stadium structure in a second horizontal direction orthogonal to the first horizontal direction. The lower stadium structure is vertically below the upper stadium structure and is interposed between the two crest regions in the second horizontal direction. The lower stadium structure comprises additional staircase structures having additional steps comprising edges of some other of the tiers. The two bridge regions are interposed between the lower stadium structure and the two of the dielectric slot structures in the first horizontal direction and extend from and between the two crest regions in the second horizontal direction. The two bridge regions have upper surfaces substantially coplanar with upper surfaces of the two crest regions.

Furthermore, in accordance with embodiments of the disclosure, a method of forming a microelectronic device comprises forming a preliminary stack structure comprising a vertically alternating sequence of sacrificial material and insulative material arranged in tiers. The preliminary stack structure further comprises rows of lower stadium structures, and a preliminary upper stadium structure. The rows of lower stadium structures extend in parallel in a first horizontal direction and each comprising two of the lower stadium structures substantially aligned with another in a second horizontal direction orthogonal to the first horizontal direction. Each of the lower stadium structures comprises staircase structures having steps comprising edges of a lower group of the tiers of the preliminary stack structure. The preliminary upper stadium structure vertically overlies the rows of lower stadium structures and comprises additional staircase structures having additional steps comprising edges of an upper group of the tiers of the preliminary stack structure. The preliminary upper stadium structure continuously extends in the second horizontal direction across multiple of the rows of lower stadium structures. The preliminary stack structure is divided into blocks separated from one another by slots. Each of the blocks comprises an upper stadium structure, one of the rows of lower stadium structures, a crest region, and bridge regions. The upper stadium structure comprises a portion of the preliminary upper stadium structure and extends in the second horizontal direction from and between two of the slots. The crest region is interposed between the two of the lower stadium structures of the one of the rows of lower stadium structures in the first horizontal direction. The bridge regions are integral with the crest region and are interposed between the two of the lower stadium structures and the two of the slots in the second horizontal direction. The sacrificial material of the preliminary stack structure is replaced with conductive material by way of the slots.

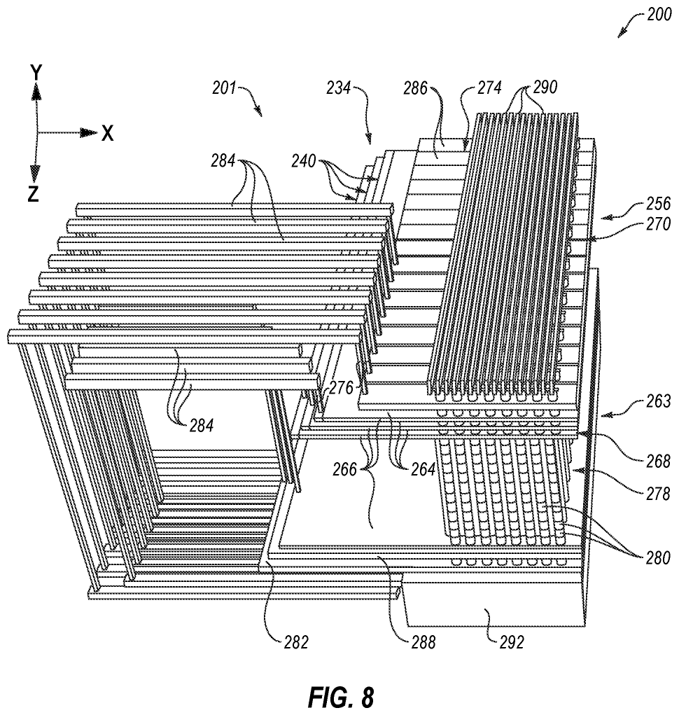

Microelectronic device structures (e.g., the microelectronic device structure 100 previously described with reference to FIGS. 7A through 7C) of the disclosure may be included in microelectronic devices of the disclosure. For example, FIG. 8 illustrates a partial cutaway perspective view of a portion of a microelectronic device 201 (e.g., a memory device, such as a 3D NAND Flash memory device) including a microelectronic device structure 200. The microelectronic device structure 200 may be substantially similar to of the microelectronic device structure 100 previously described with reference to FIGS. 7A through 7C. In FIG. 8 and the associated description, functionally similar features (e.g., structures, materials) are referred to with similar reference numerals incremented by 100. To avoid repetition, not all features shown in FIG. 8 are described in detail herein. Rather, unless described otherwise below, a feature designated by a reference numeral that is a 100 increment of the reference numeral of a previously described feature will be understood to be substantially similar to the previously described feature. By way of non-limiting example, unless described otherwise below, a feature designated by the reference numeral 234 in FIG. 8 will be understood to be substantially similar to the upper stadium structure 134 (including the opposing staircase structures 136 and the central region 138 thereof) previously described herein with reference to FIGS. 5A through 7C. In addition, for clarity and ease of understanding the drawings and associated description, some features (e.g., structures, materials, regions, sections) of the microelectronic device structure 100 previously described herein are not shown in FIG. 8. However, it will be understood that any features of the microelectronic device structure 100 at the processing stage previously described with reference to one or more of FIGS. 7A through 7C may be included in the microelectronic device structure 200 of the microelectronic device 201 described herein with reference to FIG. 8.

As shown in FIG. 8, in addition to the features of the microelectronic device structure 200 previously described herein in relation to the microelectronic device structure 100 (FIGS. 7A through 7C), the microelectronic device 201 may further include cell pillar structures 278 vertically extending through individual blocks 256 of the stack structure 263. The cell pillar structures 278 may be positioned within memory array regions of the blocks 256 horizontally offset (e.g., in the X-direction) from the upper stadium structures 234 within the blocks 256. Intersections of the cell pillar structures 278 and the conductive structures 266 of the tiers 268 of the blocks 256 of the stack structure 263 form strings of memory cells 280 vertically extending through each block 256 of the stack structure 202. For each string of memory cells 280, the memory cells 280 thereof may be coupled in series with one another. Within each block 256, the conductive structures 266 of some of the tiers 268 thereof may serve as access line structures (e.g., word line structures) for the strings of memory cells 280 within the horizontal area of the block 256. In some embodiments, within each block 256, the memory cells 280 formed at the intersections of the conductive structures 266 of some of the tiers 268 and the cell pillar structures 278 comprise so-called “MONOS” (metal-oxide-nitride-oxide-semiconductor) memory cells. In additional embodiments, the memory cells 280 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 280 comprise so-called “floating gate” memory cells including floating gates (e.g., metallic floating gates) as charge storage structures. The floating gates may horizontally intervene between central structures of the cell pillar structures 278 and the conductive structures 266 of the different tiers 268 of the stack structure 263.

The microelectronic device 201 may further include at least one source structure 282, conductive routing structures 284, first select gates 286 (e.g., upper select gates, drain select gates (SGDs)), one or more second select gates 288 (e.g., lower select gates, source select gate (SGSs)), and digit line structures 290. The digit line structures 290 may vertically overlie and be coupled to the cell pillar structures 278 (and, hence, the strings of memory cells 280). The first select gates 286 of an individual block 256 interposed between dielectric slot structures 270 may be separated from one another by the additional dielectric slot structures 274. The source structure 282 may vertically underlie and be coupled to the cell pillar structures 278 (and, hence, the strings of memory cells 280). In addition, the second contact structures 276 may couple various features of the microelectronic device 201 to one another as shown (e.g., the conductive routing structures 284 to the first select gates 286 and the conductive structures 266 of the tiers 268 of the blocks 256 of the stack structure 263).

The microelectronic device 201 may also include abase structure 292 positioned vertically below the cell pillar structures 278 (and, hence, the strings of memory cells 280). The base structure 292 may include at least one control logic region including control logic devices configured to control various operations of other features (e.g., the strings of memory cells 280) of the microelectronic device 201. As a non-limiting example, the control logic region of the base structure 292 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base structure 292 may be coupled to the source structure 282, the conductive routing structures 284, and the digit line structures 290. In some embodiments, the control logic region of the base structure 292 includes CMOS (complementary metal-oxide-semiconductor) circuitry. In such embodiments, the control logic region of the base structure 292 may be characterized as having a “CMOS under Array” (“CuA”) configuration.

Thus, in accordance with embodiments of the disclosure, a memory device comprises a stack structure, and strings of memory cells. The stack structure comprises tiers each comprising a conductive material and an insulative material vertically neighboring the conductive material. The stack structure is divided into blocks extending in parallel in a first direction and separated from one another in a second direction by dielectric slot structures. Each of the blocks comprises an upper stadium structure, lower stadium structures, crest regions, and bridge regions. The upper stadium structure comprises opposing staircase structures having steps comprising edges of an upper group of the tiers of the stack structure. The upper stadium structure extends in the second direction from and between two of the dielectric slot structures. The lower stadium structures are vertically below the upper stadium structure and each comprise additional opposing staircase structures having additional steps comprising edges of a lower group of the tiers of the stack structure. The crest regions are interposed between the lower stadium structures in the first direction. The bridge regions are integral with the crest regions and are interposed between the lower stadium structures and the two of the dielectric slot structures in the second direction. The strings of memory cells vertically extend through a portion of each of the blocks neighboring the upper stadium structure in the first direction.

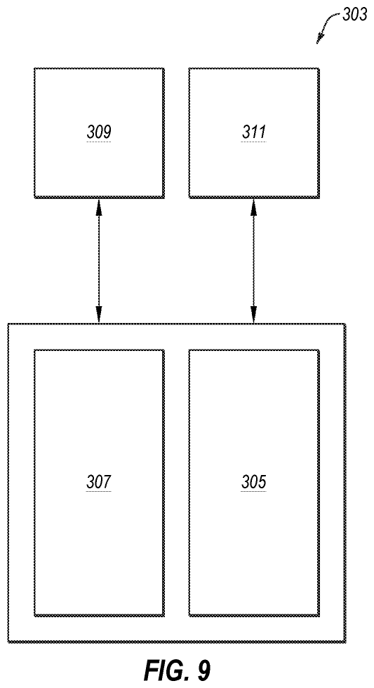

Microelectronic devices structures (e.g., the microelectronic device structure 100 previously described with reference to FIGS. 7A through 7C) and microelectronic devices (e.g., the microelectronic device 201 (FIG. 8)) in accordance with embodiments of the disclosure may be used in embodiments of electronic systems of the disclosure. For example, FIG. 9 is a block diagram of an illustrative electronic system 303 according to embodiments of disclosure. The electronic system 303 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 303 includes at least one memory device 305. The memory device 305 may comprise, for example, one or more of a microelectronic device structure (e.g., the microelectronic device structure 100 previously described with reference to FIGS. 7A through 7C) and a microelectronic device (e.g., the microelectronic device 201 (FIG. 8)) previously described herein. The electronic system 303 may further include at least one electronic signal processor device 307 (often referred to as a “microprocessor”). The electronic signal processor device 307 may, optionally, include one or more of a microelectronic device structure (e.g., the microelectronic device structure 100 previously described with reference to FIGS. 7A through 7C) and a microelectronic device (e.g., the microelectronic device 201 (FIG. 8)) previously described herein. While the memory device 305 and the electronic signal processor device 307 are depicted as two (2) separate devices in FIG. 8, in additional embodiments, a single (e.g., only one) memory/processor device having the functionalities of the memory device 305 and the electronic signal processor device 307 is included in the electronic system 303. In such embodiments, the memory/processor device may include one or more of a microelectronic device structure (e.g., the microelectronic device structure 100 previously described with reference to FIGS. 7A through 7C) and a microelectronic device (e.g., the microelectronic device 201 (FIG. 8)) previously described herein. The electronic system 303 may further include one or more input devices 309 for inputting information into the electronic system 303 by a user, such as, for example, a mouse or other pointing device, a keyboard, a touchpad, a button, or a control panel. The electronic system 303 may further include one or more output devices 311 for outputting information (e.g., visual or audio output) to a user such as, for example, a monitor, a display, a printer, an audio output jack, a speaker, etc. In some embodiments, the input device 309 and the output device 311 comprise a single touchscreen device that can be used both to input information to the electronic system 303 and to output visual information to a user. The input device 309 and the output device 311 may communicate electrically with one or more of the memory device 305 and the electronic signal processor device 307.

Thus, in accordance with embodiments of the disclosure, an electronic system comprises an input device, an output device, a processor device operably coupled to the input device and the output device, and a memory device operably coupled to the processor device. The memory device comprises at least one microelectronic device structure comprising a stack structure, conductive contact structures, and strings of memory cells. The stack structure has a vertically alternating sequence of conductive material and insulative material arranged in tiers. The stack structure comprises blocks separated from one another by dielectric slot structures. At least one of the blocks comprises an upper stadium structure, lower stadium structures, first elevated regions, and second elevated regions. The upper stadium structure comprises opposing staircase structures having steps comprising edges of an upper group of the tiers of the stack structure. The upper stadium structure extends in a first direction from and between two of the dielectric slot structures. The lower stadium structures are vertically below the upper stadium structure and each comprise additional opposing staircase structures having additional steps comprising edges of a lower group of the tiers of the stack structure. The first elevated regions intervene between the lower stadium structures in a second direction orthogonal to the first direction. The second elevated regions are integral with the first elevated regions and are interposed between the lower stadium structures and the two of the dielectric slot structures in the first direction. The conductive contact structures land on the steps and the additional steps of the at least one of the blocks. The strings of memory cells vertically extend through the at least one of the blocks.

The structures, devices, system, and methods of the disclosure advantageously facilitate one or more of improved microelectronic device performance, reduced costs (e.g., manufacturing costs, material costs), increased miniaturization of components, and greater packaging density as compared to conventional structures, conventional devices, conventional systems, and conventional methods. The structures, devices, systems, and methods of the disclosure may also improve scalability, efficiency, and simplicity as compared to conventional structures, conventional devices, conventional systems, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

1. A microelectronic device, comprising:
a stack structure comprising blocks separated from one another by dielectric slot structures and each including a vertically alternating sequence of conductive structures and insulative structures arranged in tiers, at least one of the blocks comprising:
an upper stadium structure extending in a first horizontal direction from and between two of the dielectric slot structures, the upper stadium structure comprising staircase structures having steps comprising edges of some of the tiers;
two crest regions offset from the upper stadium structure in a second horizontal direction orthogonal to the first horizontal direction;
a lower stadium structure vertically below the upper stadium structure and interposed between the two crest regions in the second horizontal direction, the lower stadium structure comprising additional staircase structures having additional steps comprising edges of some other of the tiers; and
two bridge regions interposed between the lower stadium structure and the two of the dielectric slot structures in the first horizontal direction and extending from and between the two crest regions in the second horizontal direction, the two bridge regions having upper surfaces substantially coplanar with upper surfaces of the two crest regions.

2. The microelectronic device of claim 1, further comprising additional dielectric slot structures partially vertically extending through the at least one of the blocks, the additional dielectric slot structures vertically overlying the lower stadium structure and extending in the second horizontal direction into a horizontal area of the upper stadium structure.

3. The microelectronic device of claim 1, further comprising conductive contact structures physically contacting the steps of the upper stadium structure and the additional steps of the lower stadium structure.

4. The microelectronic device of claim 1, further comprising a filled trench vertically overlying and within a horizontal area of the upper stadium structure of the at least one of the blocks, the filled trench comprising:
a first dielectric liner on the staircase structures of the upper stadium structure and extending in the first horizontal direction from and between two of the dielectric slot structures;
a second dielectric liner on the first dielectric liner and having a different material composition than the first dielectric liner; and
a first dielectric fill material on the second dielectric liner.

5. The microelectronic device of claim 4, further comprising an additional filled trench vertically overlying and within a horizontal area of the lower stadium structure of the at least one of the blocks, the additional filled trench comprising:
a fourth dielectric liner on the additional staircase structures of the lower stadium structure and on lower portions of inner sidewalls of the two bridge regions; and
a fifth dielectric liner on the fourth dielectric liner and having a different material composition than the fourth dielectric liner; and
a second dielectric fill material on the fifth dielectric liner.

6. The microelectronic device of claim 5, wherein:
the first dielectric liner and the fourth dielectric liner each comprise silicon oxide;
the second dielectric liner comprises one or more of silicon oxynitride and silicon carboxynitride; and
fifth dielectric liner comprises one or more of silicon nitride, silicon oxynitride, and silicon carboxynitride.

7. The microelectronic device of claim 5, wherein:
the first dielectric liner and the fourth dielectric liner each comprise a first dielectric material;
the second dielectric liner comprises a second dielectric material different than the first dielectric material; and
the fifth dielectric liner comprises a third dielectric material different than each of the first dielectric material and the second dielectric material.

8. The microelectronic device of claim 7, wherein:
the first dielectric material comprises dielectric oxide material;
the second dielectric material comprises one or more of dielectric oxynitride material and dielectric carboxynitride material; and
the third dielectric material comprises a dielectric nitride material.

9. The microelectronic device of claim 7, wherein the first dielectric fill material and the second dielectric fill material each comprise the first dielectric material.

10. The microelectronic device of claim 5, wherein the additional filled trench further comprises:
a sixth dielectric liner vertically overlying the fourth dielectric liner and on upper portions of the inner sidewalls of the two bridge regions; and
a seventh dielectric liner on the sixth dielectric liner and having a different material composition than the sixth dielectric liner; and
a third dielectric fill material on the seventh dielectric liner.

11. The microelectronic device of claim 10, wherein:
the first dielectric liner and the sixth dielectric liner each comprise a first dielectric material; and
the second dielectric liner and the seventh dielectric liner each comprise a second dielectric material different than the first dielectric material.

12. The microelectronic device of claim 11, wherein:
the first dielectric material comprises dielectric oxide material; and
the second dielectric material comprises dielectric nitride material.

13. The microelectronic device of claim 11, wherein:
the fourth dielectric liner comprises the first dielectric material; and
the fifth dielectric liner comprises a third dielectric material different than each of the first dielectric material and the second dielectric material.

14. The microelectronic device of claim 10, wherein the first dielectric fill material, the second dielectric fill material, and the third dielectric fill material each have substantially the same material composition as one another.

15. A method of forming a microelectronic device, comprising:
forming a preliminary stack structure comprising a vertically alternating sequence of sacrificial material and insulative material arranged in tiers, the preliminary stack structure further comprising:
rows of lower stadium structures extending in parallel in a first horizontal direction and each comprising two of the lower stadium structures substantially aligned with another in a second horizontal direction orthogonal to the first horizontal direction, each of the lower stadium structures comprising staircase structures having steps comprising edges of a lower group of the tiers of the preliminary stack structure; and
a preliminary upper stadium structure vertically overlying the rows of lower stadium structures and comprising additional staircase structures having additional steps comprising edges of an upper group of the tiers of the preliminary stack structure, the preliminary upper stadium structure continuously extending in the second horizontal direction across multiple of the rows of lower stadium structures;
dividing the preliminary stack structure into blocks separated from one another by slots, each of the blocks comprising:
an upper stadium structure comprising a portion of the preliminary upper stadium structure, the upper stadium structure extending in the second horizontal direction from and between two of the slots;
one of the rows of lower stadium structures;
a crest region interposed between the two of the lower stadium structures of the one of the rows of lower stadium structures in the first horizontal direction; and
bridge regions integral with the crest region and interposed between the two of the lower stadium structures and the two of the slots in the second horizontal direction; and
replacing the sacrificial material of the preliminary stack structure with conductive material by way of the slots.

16. The method of claim 15, wherein forming the preliminary stack structure comprises:
forming the lower group of the tiers;
forming first trenches within the lower group of the tiers to form the rows of lower stadium structures;
filling the first trenches with dielectric materials to form first filled trenches;
forming the upper group of the tiers over and across the lower group of the tiers and the first filled trenches;
forming a second trench within the upper group of the tiers to form the preliminary upper stadium structure;
forming third trenches within the upper group of the tiers to expose the first filled trenches; and
filling the second trench and the third trenches with additional dielectric materials.

17. The method of claim 16, wherein forming the second trench and forming the third trenches comprises forming the second trench substantially simultaneously with forming the third trenches.

18. The method of claim 16, wherein forming the second trench and forming the third trenches comprises forming the third trenches after forming the second trench.

19. The method of claim 16, wherein filling the first trenches with dielectric materials comprises:
forming a first dielectric material on surfaces of the lower group of the tiers defining the first trenches;
forming a second dielectric material on the first dielectric material, the second dielectric material having a different material composition than the first dielectric material; and
forming a third dielectric material on the second dielectric material, the third dielectric material having a different material composition than the second dielectric material.

20. The method of claim 19, further comprising:
selecting the first dielectric material to comprise silicon dioxide;
selecting the second dielectric material to comprise silicon nitride; and
selecting the third dielectric material to comprise additional silicon dioxide.

21. The method of claim 19, wherein filling the second trench and the third trenches with additional dielectric materials comprises:
forming a fourth dielectric material on surfaces of the upper group of the tiers defining the second trench and the third trenches;
forming a fifth dielectric material on the third dielectric material, the fifth dielectric material having a different material composition than the fourth dielectric material; and
forming a sixth dielectric material on the fifth dielectric material, the sixth dielectric material having a different material composition than the fifth dielectric material.

22. The method of claim 21, further comprising:
selecting the first dielectric material, the third dielectric material, the fourth dielectric material, and the sixth dielectric material to each comprise silicon oxide;
selecting the second dielectric material to comprise one or more of silicon nitride, silicon oxynitride, and silicon carboxynitride; and
selecting the fifth dielectric material to comprise one or more of silicon oxynitride and silicon carboxynitride.

23. The method of claim 15, further comprising forming first contact structures vertically extending completely through the blocks of the preliminary stack structure prior to replacing the sacrificial material of the preliminary stack structure with the conductive material.

24. The method of claim 23, further comprising forming second contact structures vertically extending partially through the blocks of the preliminary stack structure, within one of the blocks:
a first group of the second contact structures vertically extending to at least some of the steps of the lower stadium structures of the one of the blocks; and
a second group of the second contact structures vertically extending to at least some further steps of the upper stadium structure of the one of the blocks.

25. A memory device, comprising:
a stack structure comprising tiers each comprising a conductive material and an insulative material vertically neighboring the conductive material, the stack structure divided into blocks extending in parallel in a first direction and separated from one another in a second direction by dielectric slot structures, each of the blocks comprising:
an upper stadium structure comprising opposing staircase structures having steps comprising edges of an upper group of the tiers of the stack structure, the upper stadium structure extending in the second direction from and between two of the dielectric slot structures;
lower stadium structures vertically below the upper stadium structure and each comprising additional opposing staircase structures having additional steps comprising edges of a lower group of the tiers of the stack structure;
crest regions interposed between the lower stadium structures in the first direction; and
bridge regions integral with the crest regions and interposed between the lower stadium structures and the two of the dielectric slot structures in the second direction; and
strings of memory cells vertically extending through a portion of each of the blocks neighboring the upper stadium structure in the first direction.

26. The memory device of claim 25, further comprising, within each of the blocks of the stack structure:
a first filled trench vertically overlying and within horizontal boundaries of the upper stadium structure, the first filled trench comprising multiple dielectric materials; and
second filled trenches vertically overlying and within horizontal boundaries of the lower stadium structures, each of the second filled trenches comprising multiple additional dielectric materials.

27. The memory device of claim 26, wherein at least one of the multiple dielectric materials of the first filled trench has a different material composition than any of the multiple additional dielectric materials of the each of the second filled trenches.

28. The memory device of claim 25, further comprising, within each of the blocks of the stack structure:
a first group of conductive contact structures landing on at least some of the steps of the opposing staircase structures of the upper stadium structure; and
a second group of conductive contact structures landing on at least some of the additional steps of the additional opposing staircase structures of each of the lower stadium structures.

29. The memory device of claim 28, further comprising:
digit lines overlying the stack structure and coupled to the strings of memory cells;
a source structure underlying the stack structure and coupled to the strings of memory cells;
conductive routing structures coupled to the first group of conductive contact structures and the second group of conductive contact structures; and
control logic circuitry underlying the stack structure and coupled to the source structure, the digit lines, and the conductive routing structures.

30. An electronic system, comprising:
an input device;
an output device;
a processor device operably coupled to the input device and the output device; and
a memory device operably coupled to the processor device and comprising at least one microelectronic device structure comprising:
a stack structure having a vertically alternating sequence of conductive material and insulative material arranged in tiers, the stack structure comprising blocks separated from one another by dielectric slot structures, at least one of the blocks comprising:
an upper stadium structure comprising opposing staircase structures having steps comprising edges of an upper group of the tiers of the stack structure, the upper stadium structure extending in a first direction from and between two of the dielectric slot structures;
lower stadium structures vertically below the upper stadium structure and each comprising additional opposing staircase structures having additional steps comprising edges of a lower group of the tiers of the stack structure;
first elevated regions intervening between the lower stadium structures in a second direction orthogonal to the first direction; and
second elevated regions integral with the first elevated regions and interposed between the lower stadium structures and the two of the dielectric slot structures in the first direction;
conductive contact structures landing on the steps and the additional steps of the at least one of the blocks; and
strings of memory cells vertically extending through the at least one of the blocks.
